(19) United States
(12) Patent Application Publication
(10) Pub. No.: US 2026/0086506 A1
(43) Pub. Date: Mar. 26, 2026

(54) WATCH HAVING CONDUCTIVE SIDE WALLS AND BIPLANAR ANTENNA CONFIGURATION

(71) Applicant: Garmin International, Inc., Olathe, KS (US)

(72) Inventors: Abu T. Sayem, Olathe, KS (US); Amirreza Jalali Khalilabadi, Olathe, KS (US); Rakib Hasan, Olathe, KS (US)

(21) Appl. No.: 19/302,816

(22) Filed: Aug. 18, 2025

Related U.S. Application Data
(63) Continuation-in-part of application No. 19/202,371, filed on May 8, 2025.
(60) Provisional application No. 63/696,939, filed on Sep. 20, 2024.

(51) Int. Cl. G04R 60/08; H01Q 5/314; H01Q 7/00; H01Q 21/30; H03J 1/00

(52) U.S. Cl. CPC G04R 60/08; H01Q 5/314; H01Q 7/005; H01Q 21/30; H03J 1/0008; H03J 2200/01; H03J 2200/11

(57) ABSTRACT

A wrist-worn electronic device comprises a housing, a first antenna, a second antenna, and an electrical switch. The housing includes a circumferential side wall, an electrically conductive bezel, a bezel retainer, a lower ring and an electrically conductive bottom plate. The first antenna is formed in part by a portion of the bezel and receives a first wireless signal having a first frequency in a global navigation satellite system (GNSS) band. The second antenna is formed in part by at least a portion of the bottom plate and transmits a second wireless signal to a non-terrestrial network (NTN), receives a third wireless signal from the NTN, or both. The electrical switch having a plurality of selectable positions each associated with a tuning network that causes the second antenna to transmit the second wireless signal at a second frequency and to receive the third wireless signal at a third frequency.

### CROSS-REFERENCE TO RELATED APPLICATIONS

The current patent application is a continuation-in-part of, and claims priority benefit to, co-pending and commonly assigned U.S. non-provisional patent application entitled, “WATCH WITH ADJUSTABLE-LENGTH BIPLANAR ANTENNA CONFIGURATION,” application Ser. No. 19/202,371, filed May 8, 2025, which claims the benefit under 35 U.S.C. § 119 (e) of U.S. Provisional Application Ser. No. 63/696,939, filed Sep. 20, 2024, and entitled “WATCH WITH ADJUSTABLE-LENGTH BIPLANAR SLOT ANTENNA CONFIGURATION.” The above-referenced applications are hereby incorporated by reference in their entirety into the present application.

### BACKGROUND

Wrist-worn electronic devices often include functionality that may be used to track a current location of a user wearing the device, along with distance traveled, velocity, and other performance metrics or data. The electronic device is typically utilized by people who are walking, jogging, running, biking, hiking, backpacking, camping, mountain climbing, geocaching, or the like. This functionality may be provided by receiving location signals from a satellite-based positioning system, such as the global navigation satellite system (GNSS).

Handheld electronic devices often include functionality that may be used to wirelessly communicate with a non-terrestrial wireless network (NTN), which includes satellite communication networks that enable two-way wireless communications between the handheld electronic devices and devices and systems connected via the NTN, as well as terrestrial communication networks (TCN), such as cellular networks that implement wireless telecommunication standards, such as long term evolution (LTE). Similar to terrestrial communication networks (TCN), the NTNs include one or more satellites configured to transmit electronic signals to the handheld electronic devices (downlink) and receive electronic signal from the electronic devices (uplink). Conventional electronic devices that are capable of supporting the frequencies used for NTN communications (uplink frequencies and downlink frequencies) typically utilize a large housing, such as a handheld device or a cellular phone (e.g., a smart phone), that accommodates one or more antennas to wirelessly transmit electronic signals to satellites and wirelessly receive electronic signals output by satellites.

At certain times, the user may engage in activities in geographically remote locations that are not within a coverage area of cellular networks or other terrestrial communication networks (TCN). In other situations, the user may travel internationally, particularly to different continents in which terrestrial networks use different frequencies for communications than the terrestrial communication networks (TCN) that are typically used by the user. As LTE and other telecommunication standards used by terrestrial cellular networks utilize different frequency bands in different continents or large geographic regions, conventional electronic devices that are configured to communicate using frequency band(s) designated for a continent or a region other than the current geographic location may be unable to use the terrestrial communication networks (TCN) available at the user's current geographic location for communication.

### SUMMARY

Embodiments of the present technology provide a wrist-worn electronic device that automatically selects an appropriate frequency for an antenna to enable communication with a non-terrestrial network (NTN) and/or a terrestrial network, such as a cellular network, based on a current geolocation of the electronic device or as desired by the user. The electronic device broadly comprises a bezel retainer, a lower ring, a housing, a first antenna, a second antenna, a first plurality of tuning networks and a first electrical switch. The housing includes a circumferential side wall, a bezel coupled to an upper surface of the bezel retainer, and a bottom plate coupled to a lower surface of the lower ring. The bezel, the side wall and the bottom plate are each formed from electrically conductive material. The first antenna is formed in part by a first portion of a circumference of the bezel and is configured to receive a first wireless signal, the first wireless signal being a first location signal, having a first frequency in a first frequency group including a first of a plurality of global navigation satellite system (GNSS) bands. The second antenna is formed in part by at least a first portion of a circumference of the bottom plate and is configured to transmit a second wireless signal to a non-terrestrial network (NTN), receive the second wireless signal from the NTN, or both. The second wireless signal has a second frequency. The first plurality of tuning networks includes tuning networks that are each configured to tune the second antenna once electrically coupled with the second antenna. The electrical switch is electrically coupled with the second antenna and includes a plurality of selectable positions. Each selectable position of the first electrical switch electrically couples the second antenna with a respective one of the first plurality of tuning networks. A first tuning network causes the second antenna to transmit the second wireless signal at a second frequency and receive the third wireless signal at a third frequency, the second frequency and the third frequency being in a second frequency group.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present technology will be apparent from the following detailed description of the embodiments and the accompanying drawing figures.

### BRIEF DESCRIPTION OF DRAWINGS

Embodiments of the present technology are described in detail below with reference to the attached drawing figures, wherein:

FIG. 1 is an environmental view of an electronic device, constructed in accordance with various embodiments of the current technology, including a plurality of antennas configured to receive location signals from global navigation satellite system (GNSS) satellites, transmit and receive communication signals from non-terrestrial network (NTN) satellites and other network equipment, and transmit and receive communication signals from terrestrial communication networks (TCN), such as long term evolution (LTE) cellular towers and other network equipment and components;

FIG. 2 is a top plan view of the electronic device including a wrist strap;

FIG. 3 is an upper perspective exploded view of the electronic device of FIG. 1 with a display, a bezel and a bezel retainer (upper ring) removed from other portions of the housing to reveal an internal cavity formed in part by side walls that are formed from an electrically non-conductive material, the internal cavity including a printed circuit board, a location determining element, a communication element, and a plurality of bezel conductive elements;

FIG. 4A is a lower perspective exploded view of the electronic device of FIG. 1 with a bottom plate removed from other portions of the housing to reveal the internal cavity including a plurality of bottom plate conductive elements;

FIG. 4B is a lower perspective exploded view of the electronic device of FIG. 1 with a bottom plate removed from other portions of the housing to reveal the lower ring and the internal cavity including a plurality of bottom plate conductive elements;

FIG. 5 is a schematic block diagram illustrating the communication between various components of the electronic device of FIG. 1;

FIG. 6 is a schematic diagram of a general form of a slot antenna;

FIG. 7A is a schematic diagram of a plurality of antennas implemented in the electronic device of FIG. 1 on at least two vertically-separated horizontal planes, with a printed circuit board forming a lower conductor of those antennas and a lower antenna formed in part by a portion of a circumference of the bottom plate;

FIG. 7B is a schematic diagram of a plurality of antennas implemented in the electronic device of FIG. 1 on at least two vertically-separated horizontal planes, with a printed circuit board forming a lower conductor of those antennas and a lower antenna formed by a circumference of the bottom plate;

FIG. 7C is a schematic diagram of a plurality of antennas implemented in the electronic device of FIG. 1 on at least two vertically-separated horizontal planes, with a side wall formed from electrically conductive material forming a lower conductor of those antennas, an upper antenna formed in part by a portion of a circumference of a bezel and a lower antenna formed in part by a portion of a circumference of the bottom plate;

FIG. 7D is a schematic diagram of a plurality of antennas implemented in the electronic device of FIG. 1 on at least two vertically-separated horizontal planes, with a side wall formed from electrically conductive material forming a lower conductor of those antennas, an upper antenna formed in part by a portion of a circumference of a bezel and a lower antenna formed by a circumference of the bottom plate;

FIG. 8A is a schematic diagram of the structural components of a first antenna configured as a slot antenna of the electronic device of FIG. 1 for receiving GNSS signals;

FIG. 8B is a simplified schematic representation with highlights of a first portion of the bezel, the bezel conductive elements, and the printed circuit board which form the first antenna of the electronic device of FIG. 1;

FIG. 8C is a top plan view of the electronic device of FIG. 1 illustrating a location of a plurality of bezel conductive elements along with the first portion of the bezel occupied by the first antenna;

FIG. 9A is a schematic diagram of the components of a second antenna configured as a slot antenna of the electronic device of FIG. 1 for transmitting and receiving cellular signals and NTN signals;

FIG. 9B is a simplified schematic representation with highlights of a portion of the bottom plate, the bottom plate conductive elements, and the printed circuit board which form the second antenna of the electronic device of FIG. 1;

FIG. 9C is a bottom plan view of the electronic device of FIG. 1 illustrating a location of a plurality of bottom plate conductive elements along with a portion of a circumference of the bottom plate occupied by the second antenna configured as a slot antenna;

FIG. 9D is a bottom plan view of the electronic device of FIG. 1 illustrating a location of a plurality of bottom plate conductive elements along with a circumference of the bottom plate occupied by the second antenna configured as a loop antenna;

FIG. 10A is a schematic diagram of the components of a third antenna configured as a slot antenna of the electronic device of FIG. 1 for transmitting and receiving communications signals;

FIG. 10B is a simplified schematic representation with highlights of a second portion of the bezel, the bezel conductive elements, and the printed circuit board which form the third antenna of the electronic device of FIG. 1;

FIG. 10C is a top plan view of the electronic device of FIG. 1 illustrating a location of a plurality of bezel conductive elements along with the second portion of the bezel occupied by the third antenna;

FIG. 11 is a schematic block diagram illustrating the components of a dynamic tuning circuit;

FIG. 12 is a schematic block diagram of another configuration of various components of the electronic device; and

FIG. 13 is a table listing wireless signals, and corresponding exemplary frequencies, transmitted or received by the first antenna, the second antenna and the third antenna.

The drawing figures do not limit the present technology to the specific embodiments disclosed and described herein. The drawings are not necessarily to scale, emphasis instead being placed upon clearly illustrating the principles of the technology.

### DETAILED DESCRIPTION OF THE TECHNOLOGY

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the present technology. The following detailed description is, therefore, not to be taken in a limiting sense. The scope of the present technology is defined only by the appended claims, along with the full scope of equivalents to which such claims are entitled.

Relational and/or directional terms, such as “above”, “below”, “up”, “upper”, “upward”, “down”, “lower”, “downward”, “top”, “bottom”, “outer”, “inner”, “left”, “right”, etc., along with orientation terms, such as “horizontal” and “vertical”, may be used throughout this description. These terms retain their commonly accepted definitions and are used with reference to embodiments of the technology and the positions, directions, and orientations thereof shown in the accompanying figures. However, embodiments of the technology in practice may be positioned and oriented in other ways or move in other directions. Therefore, the terms do not limit the scope of the current technology.

Wrist-worn electronic devices, including smartwatches, often include a first antenna and a location determining element that are configured to receive global navigation satellite system (GNSS) wireless signals (location signals) that are used to determine a current geolocation of a user wearing the device, a distance traveled, a velocity, and other performance metrics or data. In addition, such wrist-worn electronic devices may include a communication element, a second antenna and other components that are configured to provide bi-directional communications, such as sending and receiving text messages, using terrestrial communication networks (TCN) and related equipment and systems. For instance, the terrestrial communications (TCN) may be cellular communications implemented using wireless telecommunication standards, such as long term evolution (LTE), that utilize a plurality of geographically distributed cellular towers each having a plurality of antennas to provide communication capabilities to devices located within their respective geographic areas (cells). Typically, the conventional wrist-worn electronic devices may utilize terrestrial communications for as long as the electronic devices are within a coverage area of the terrestrial communication networks (TCN) by being geographically located proximate to associated network equipment, such as a cell tower. Once such electronic devices are moved to a geographically remote location that is not within the coverage area of the terrestrial communication networks (TCN) and is not proximate to associated network systems and equipment, such as a cell tower, the electronic devices are not able to communicate through the terrestrial networks. If alternate means of connectivity are available using a separate electronic device, such as a portable or a mobile electronic device having antennas that are capable of wirelessly connecting to the wrist-worn electronic device, the wrist-worn electronic device may communicate using networks through which the portable or a mobile electronic device has connectivity, which may include non-terrestrial networks. For example, a wrist-worn electronic device may be paired with a handheld satellite communicator or a mobile phone (e.g., smart phone) capable of satellite communications that enables the wrist-worn electronic device to send and receive data, messages and other information. The wrist-worn electronic device may utilize the handheld satellite communicator or the mobile phone to enable such satellite-based communications until the wrist-worn electronic device returns to a geographic location that is proximate to (and in the coverage area of) terrestrial communication networks (TCN).

Terrestrial communication networks (TCN), such as cellular networks typically use one or more predetermined frequency bands for communications that occur between cellular towers and electronic devices. As the coverage area of the terrestrial communication networks (TCN) are limited to geographic locations in which associated equipment (e.g., a cell tower) is located, the frequency bands used by cellular networks are often specific to a continent or geographic region, which limits the compatibility of electronic devices to terrestrial communication networks (TCN) that support communications using the frequencies on which the electronic devices may transmit or receive electronic signals. For example, use of a first frequency band may be supported by cellular networks in North America, use of a second frequency band may be supported by cellular networks in Europe, and so forth. For conventional electronic devices that are configured to transmit and receive electronic signals on certain frequencies that are used by terrestrial communication networks (TCN) in a continent or region, a user who travels with that conventional electronic device to a different continent or region may not be able to use a local terrestrial communication network (TCN) in that continent or region if it operates at different frequencies.

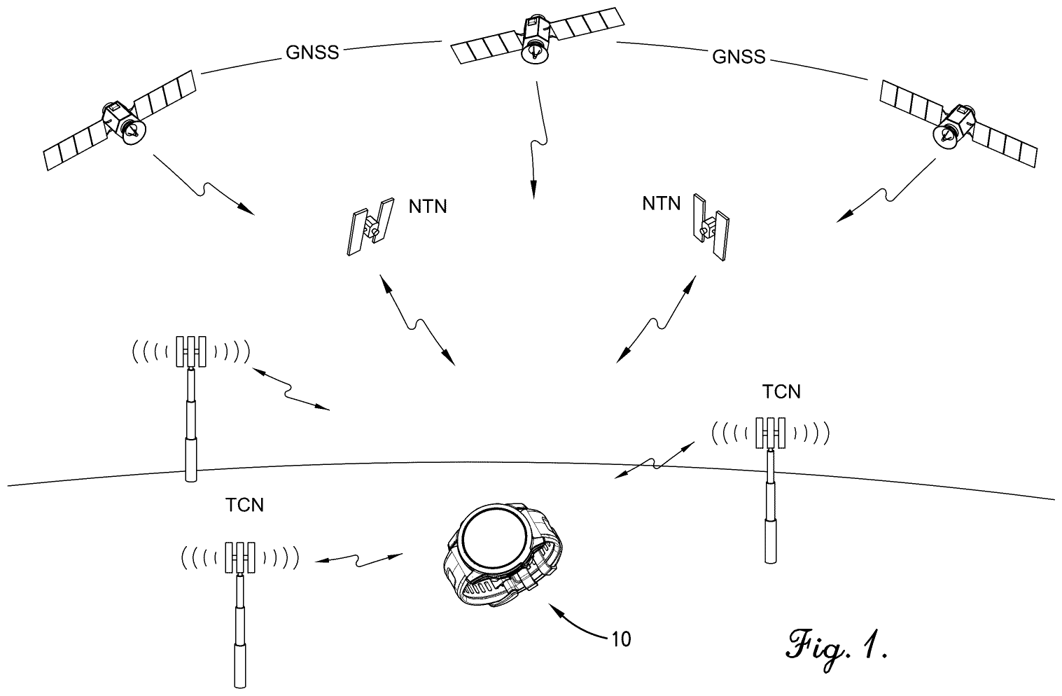

Referring to FIG. 1, embodiments of the current technology provide a wrist-worn electronic device 10 configured to wirelessly receive wireless signals output by GNSS satellites (location signals), wirelessly transmit and receive electronic signals to and from a non-terrestrial network (NTN) and wirelessly transmit and receive electronic signals to and from terrestrial networks and systems, such as cellular networks. The electronic device 10 includes a first antenna configured to wirelessly receive the location signals (GNSS wireless signals), such as location signals having a frequency corresponding to the L1 band or the L5 band of the global positioning system (GPS). The electronic device 10 includes a second antenna configured to wirelessly transmit and receive electronic signals having a frequency corresponding to one or more frequencies in one or more NTN frequency bands, one or more cellular frequency bands, or both. The electronic device 10 further includes a third antenna configured to wirelessly transmit electronic signals to a terrestrial personal network and receive electronic signals from the terrestrial personal network, such as a Wi-Fi network or a Bluetooth™ connection.

The NTN communication networks and systems include a plurality of satellites and at least one ground-based gateway station. Each satellite of the NTN provides communication between electronic devices, such as electronic device 10, located in a geographic area (service cell) below the satellite and other NTN equipment, which includes other satellites and a gateway station. Similar to handheld electronic devices capable of communicating with a satellite of the NTN, the electronic device 10 may communicate with a satellite from any geographic location having visibility to the satellite that is within a service cell of the satellite, which may be a coverage area on or above the Earth's surface formed by geographic locations from which electronic signals may be received from the satellite or transmitted to the satellite. For example, the electronic device 10 may transmit electronic signals to or receive electronic signals from a satellite of the NTN while it is located on the surface of the Earth (e.g., worn by a user on a hiking trail, worn by a user in a marine vessel on a body of water, etc.) or above the surface of the Earth (e.g., worn by a user in an aircraft, worn by a user on the roof of a building, etc.).

Each satellite of the NTN may serve as a base station that relays electronic signals bidirectionally between the electronic device 10 while it is present in a service cell and a ground-based gateway station, other satellites of the NTN or the other equipment of the NTN. For example, a satellite of the NTN may wirelessly receive electronic signals transmitted by the electronic device 10 while it is located in a service cell of the satellite using a user link (an uplink) and then wirelessly transmit the received electronic signals to a ground-based gateway station using one or more feeder links (a downlink). Similarly, a satellite of the NTN may wirelessly receive electronic signals transmitted by a ground-based gateway station using one or more feeder links (an uplink) and then wirelessly transmit the received electronic signals to the electronic device 10 while it is located in a service cell using a user link (a downlink). The NTN uses and supports the use of electronic signals on multiple frequencies. For instance, other than the communications with the electronic device 10 and other electronic devices located in its service cell, each satellite of the NTN typically uses feeder links that connect the satellite to the ground-based equipment and terrestrial networks (as each satellite of the NTN aggregates the signals that are relayed between electronic devices in its service cell and the ground-based gateway station, the feeder links utilize different frequencies and have higher capacity than user links between the satellite and electronic devices in its service cell). The NTN also typically uses the feeder links between satellites of the NTN and the ground-based gateway stations of the NTN to support and maintain connections between the electronic device 10 and one or more satellites of the NTN to support the core services provided by the NTN. As each ground-based gateway station may be communicatively coupled with other equipment of the NTN and one or more terrestrial networks (e.g., cellular networks, the Internet, etc.), the electronic device 10 may use the NTN to maintain communications with other electronic devices and systems while the electronic device 10 is not within the coverage area of terrestrial communication networks (TCN).

The satellites of the NTN include low-earth orbit (LEO) satellites, medium-earth orbit (MEO) satellites geosynchronous-earth orbit (GEO) satellites, or any combination thereof. For example, the NTN may include low-earth orbit (LEO) satellites that typically orbit at altitudes between 400 km and 3,000 km above sea level, medium-earth orbit (MEO) satellites that typically orbit at altitudes between 3,000 km and 20,000 km above sea level and geostationary earth orbit (GEO) satellites that typically orbit at altitudes above 36,000 km above sea level. The GEO satellites of the NTN may be geosynchronous (GEO) satellites having an orbital position with respect to a fixed point on the Earth, such as an orbital position above a point along the equator (the GSO satellites follow a predictable path and have an orbital period that matches the rotation of the Earth). The LEO satellites of the NTN may enable electronic devices, such as the electronic device 10, to communicate with a lower latency and at higher data rates than MEO satellites or GEO satellites of the NTN. However, given the distance separating the satellites of the NTN from the electronic device 10 from and other equipment of the NTN, communication using the NTN typically occurs with greater latency and at lower data rates than terrestrial cellular networks, such as LTE networks. In many geographic areas, satellites of the NTN that are compatible with the L band may support a larger service area (wider coverage) than satellites of the NTN that may only be compatible with the S band, which may support higher data rates and bandwidth than the L band.

Each satellite of the NTN is configured to transmit electronic signals to the electronic device 10 (downlink) and receive electronic signals from the electronic device 10 (uplink) at predetermined frequencies. In embodiments, the electronic device 10 may communicate with an LEO satellite of the NTN over various bands, such as 1525-1660 MHz to support uplink and downlink frequencies for the L band and/or 1980-2200 MHz to support uplink and downlink frequencies for the S band. For example, the electronic device 10 may transmit electronic signals to an LEO satellite of the NTN using the L band at a frequency in the 1610-1660 MHz band (uplink) and receive electronic signals output by the LEO satellite of the NTN at a frequency in the 1525-1559 MHz band (downlink). Similarly, in a first geographic area (e.g., the United States), the electronic device 10 may transmit electronic signals to an LEO satellite of the NTN using the S band at a frequency in the 2000-2020 MHz band (uplink) and receive electronic signals output by the LEO satellite of the NTN at a frequency in the 2180-2200 MHz band (downlink). In a second geographic area (e.g., Europe), the electronic device 10 may transmit electronic signals to an LEO satellite of the NTN using the S band at a frequency in the 1980-2010 MHz band (uplink) and receive electronic signals output by the LEO satellite of the NTN at a frequency in the 2170-2200 MHz band (downlink).

Similarly, certain frequency bands may be used by terrestrial networks to transmit electronic signals and receive electronic signals in different continents or geographic regions. Cellular networks, such as LTE communication systems, which include terrestrial wireless broadband communication networks and are a part of, or an extension of, the fourth generation (4G) telecommunication standard, may use a first frequency band for the transmission of electronic signals by cellular towers or other network equipment to mobile devices in the United States and a second frequency band for a similar transmission in another country. That distinction may also exist for the transmission of electronic signals by mobile devices to cellular towers or other network equipment in the United States compared to another country. For example, the frequency bands used by LTE networks may include various B bands (e.g., B1, B2, B3, B4, B8, B12, B20, B28, etc.) that are utilized in North America, Central America, South America, Europe, the Middle East, Africa, Asia, Australia, and New Zealand. In some embodiments, an electronic device 10 operating on a terrestrial network using a B20 band (a 800 MHz band that is utilized in Europe, the Middle East, and Africa) may utilize an uplink frequency in a 832 MHz-862 MHz band, such as a center transmit frequency of 847 MHz, and a downlink frequency in a 791 MHz-821 MHz band, such as a center receive frequency of 806 MHz.

Given the variance in predetermined frequencies used by NTNs and terrestrial cellular networks, electronic devices must incorporate one or more antennas that are able to transmit and receive wireless signals at frequencies used by the NTNs and transmit and receive wireless signals at frequencies used by the terrestrial cellular networks (TCNs), which are typically different from the frequencies used by electronic devices that communicate with NTNs. For wrist-worn electronic devices, it is challenging to incorporate the one or more antennas that receive location signals and communicate with NTN, terrestrial networks and use common wireless communication protocols such as terrestrial personal networks using Wi-Fi or Bluetooth™, in a housing that may be comfortably worn by the user.

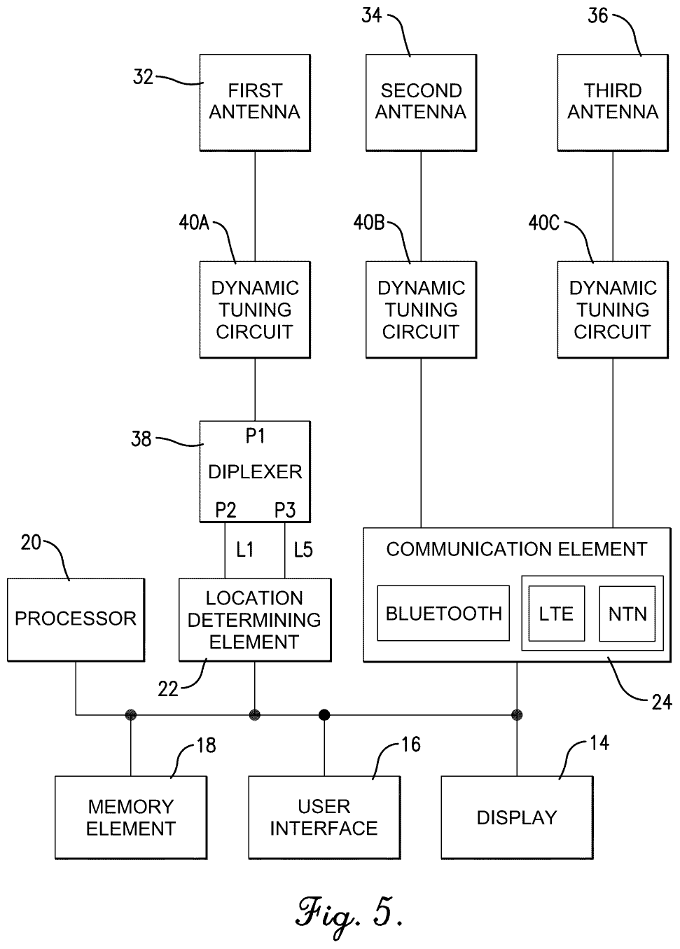

Embodiments of the technology will now be described in more detail with reference to the drawing figures. Referring initially to FIGS. 1-5, a wrist-worn electronic device 10 is illustrated. The electronic device 10 broadly comprises a housing 12, a display 14, a user interface 16, a memory element 18, a processor 20, a location determining element 22, a communication element 24, a printed circuit board 26, a plurality of bezel conductive elements 28, a plurality of bottom plate conductive elements 30, a first antenna 32, a second antenna 34, a third antenna 36, a diplexer 38, and one or more dynamic tuning circuits 40A, 40B, 40C. The electronic device 10 may also include a wrist band 42, a strap, or other attachment mechanisms. In addition, communication between various electronic components of the electronic device 10 is illustrated schematically in FIG. 5.

The housing 12, as shown in FIGS. 1-4B, generally houses or retains other components of the electronic device 10 and may include or be coupled to the wrist band 42. The housing 12 includes a bottom plate 44, a side wall 46, a bezel retainer 48, and a bezel 50. The bottom plate 44 includes an upper, inner surface and a lower, outer surface that contacts an upper surface of the user's wrist while the user is wearing the electronic device 10. The bottom plate 44 may also include one or more openings from the outer surface to the inner surface which accommodate battery charging and/or data communication connectors or the like. In addition, the bottom plate is formed from electrically conductive materials, such as metals and/or metal alloys, which are electromagnetically radiating

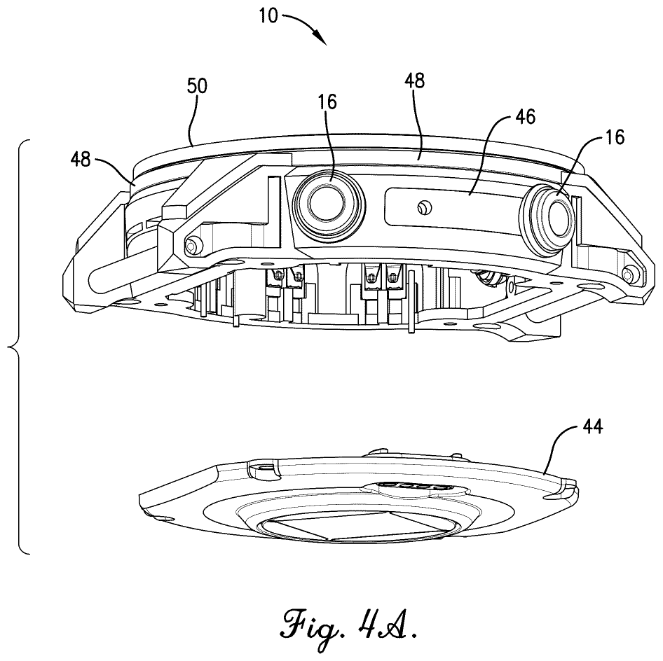

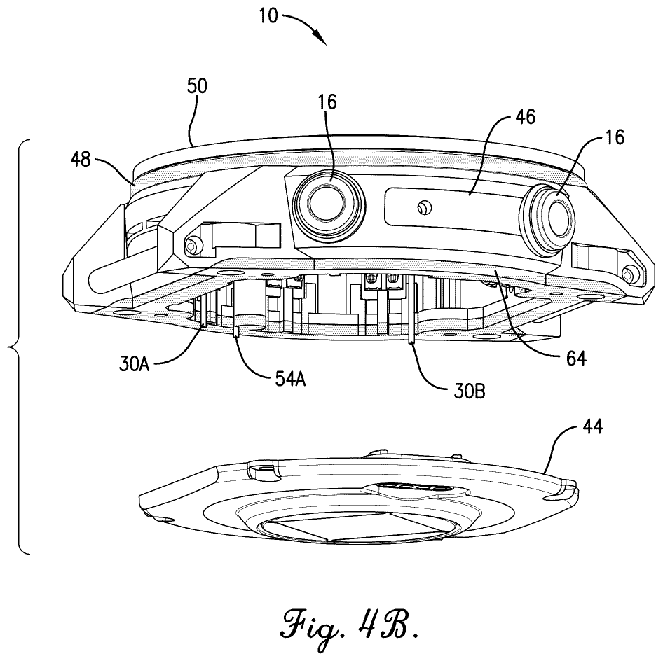

In some embodiments, as shown in FIG. 4A, the side wall 46 couples to the bottom plate 44 at a lower edge of the side wall 46. In other embodiments, as shown in FIG. 4B, the side wall 46 couples to a lower ring 64 that couples to a lower edge of the side wall 46. The side wall 46 includes an outer surface and an opposing inner surface and may have a plurality of through holes, each of which passes from the outer surface to the inner surface to retain one or more pushbuttons or other user interface 16 components. The side wall 46 may further include extensions which retain first and second bars to which the wrist band attaches.

In some embodiments, as shown in FIG. 4A, the side wall 46 is formed from electrically non-conductive (insulating) material such as plastic polymers or the like. As the printed circuit board 26 is positioned between the bezel 50 and the bottom plate 44, a portion of the bezel 50 may form an upper conductor of one or more slot antennas in the upper portion of the housing 12 and the printed circuit board 26 may form a lower conductor of those antennas. Similarly, a portion of the bottom plate 44 may be utilized to form the upper conductor of one or more slot antennas in the lower portion of the housing 12 and the printed circuit board 26 may form a lower conductor of those antennas. The bezel retainer 48 and the side wall 46, when formed from electrically non-conductive (insulating) material, do not form a portion of the slot antennas in the lower portion of the housing 12.

In other embodiments, as shown in FIG. 4B, the bezel 50 and the side wall 46 are formed of electrically conductive material, such as metals and/or metal alloys, which are electromagnetically radiating, and are separated by a bezel retainer 48. As disclosed in U.S. Pat. No. 10,271,299, some conventional wrist-worn devices include one or more antennas formed by a nonconductive slot between a bezel of an upper housing and a lower housing, each formed of an electrically conductive material and separated by a ring formed of electrically nonconductive material.

The bezel retainer 48 couples to the side wall 46 at an upper edge thereof. Similarly, the lower ring 62 couples to the side wall 46 at a lower edge thereof. The lower ring 62 is formed from electrically non-conductive (insulating) material such as plastic polymers or the like. The bezel retainer 48 and the lower ring 62 are each formed from electrically non-conductive (insulating) material such as plastic polymers or the like. In various embodiments, the bezel retainer 48 and the lower ring 62 may be integrated with the side wall 46 or may be optional, wherein the bezel 50 couples to an upper surface of the side wall 46 or the bottom plate 44 couples to a lower surface of the side wall 46. A plurality of electrical contacts may electrically couple the side wall 46 with an electrical ground of the printed circuit board 26. In such embodiments, the upper surface of the side wall 46 and the lower surface of the side wall 46 are electrically grounded.

The bezel 50 couples to the bezel retainer 48 along an upper surface thereof. The bezel 50 includes an upper surface, which in exemplary embodiments, may be substantially planar, tilted or slanted, and a lower surface that is generally planar. The bezel 50 forms a central opening through which the display 14 is visible and may, itself, retain a lens or other components that cover the display 14. The bezel 50 is formed from electrically conductive materials, such as metals and/or metal alloys, which are electromagnetically radiating.

In exemplary embodiments, the housing 12 generally has a rounded or circular shape, wherein the bottom plate 44 has a disc shape, the side wall 46 has a hollow cylindrical shape, the bezel retainer 48 has a ring shape, the lower ring 62 has a ring shape and the bezel 50 has an annular shape. In other embodiments, the housing 12 may have one of a variety of geometric or polygonal shapes, such as triangular, square or rectangular, hexagonal, octagonal, and so forth.

The display 14 may include video devices of the following types: plasma, light-emitting diode (LED), organic LED (OLED), Light Emitting Polymer (LEP) or Polymer LED (PLED), liquid crystal display (LCD), thin film transistor (TFT) LCD, LED side-lit or back-lit LCD, or the like, or combinations thereof. The display 14 may include a screen on which information is presented, with the screen possessing any one of a variety of shapes, such as a square or a rectangular aspect ratio that may be viewed in either a landscape or a portrait mode. In some embodiments, the display 14 may further include a lens and other components overlying the viewing area, which may enhance the visibility of the information shown on the display 14. In various embodiments, the display 14 may also include a touch screen occupying the entire screen or a portion thereof so that the display 14 functions as part of the user interface 16. The touch screen may allow the user to interact with the electronic device 10 by physically touching, swiping, or gesturing on areas of the screen. The display 14 may be in communication electronic with the memory element 18 and the processor 20 and may receive data or information therefrom that is to be shown on the display 14. In exemplary embodiments, the display 14 is generally surrounded by the bezel 50.

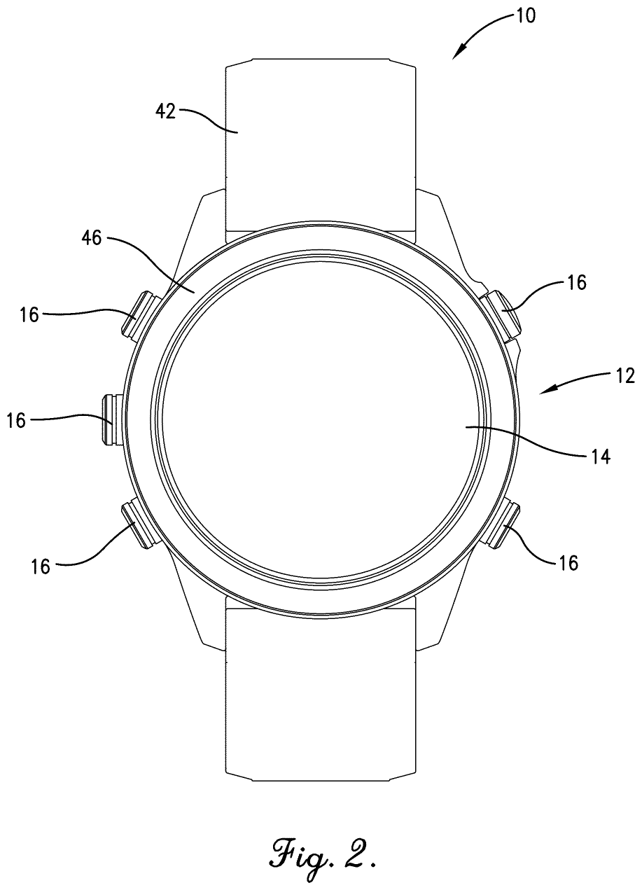

The user interface 16 generally allows the user to directly interact with the electronic device 10 and may include pushbuttons, rotary knobs, or the like. In exemplary embodiments of FIGS. 2-4B, the housing 12 may include one or more pushbuttons and/or rotary knobs located in the through holes of the side wall 46 that function as at least a portion of the user interface 16. The user interface 16 may allow the user to scroll through menus or change screens in order to control the function or operation of the electronic device 10.

The memory element 18 may be embodied by devices or components that store data in general, and digital or binary data in particular, and may include exemplary electronic hardware data storage devices or components such as read-only memory (ROM), programmable ROM, erasable programmable ROM, random-access memory (RAM) such as static RAM (SRAM) or dynamic RAM (DRAM), cache memory, solid state memory, or the like, or combinations thereof. In some embodiments, the memory element 18 may be embedded in, or packaged in the same package as, the processor 20. The memory element 18 may include, or may constitute, a non-transitory “computer-readable medium”. The memory element 18 may store the instructions, code, code statements, code segments, software, firmware, programs, applications, apps, services, daemons, or the like that are executed by the processor 20. The memory element 18 is in communication electronic with the processor 20 and may also store data that is received by the processor 20 or the device in which the processor 20 is implemented. The processor 20 may further store data or intermediate results generated during processing, calculations, and/or computations as well as data or final results after processing, calculations, and/or computations. In addition, the memory element 18 may store settings, text data, documents from word processing software, spreadsheet software and other software applications, sampled audio sound files, photograph or other image data, movie data, databases, and the like.

The processor 20 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The processor 20 may generally execute, process, or run instructions, code, code segments, code statements, software, firmware, programs, applications, apps, processes, services, daemons, or the like. The processor 20 may also include hardware components such as registers, finite-state machines, sequential and combinational logic, configurable logic blocks, and other electronic circuits that can perform the functions necessary for the operation of the current invention. In certain embodiments, the processor 20 may include multiple computational components and functional blocks that are packaged separately but function as a single unit. In some embodiments, the processor 20 may further include multiprocessor architectures, parallel processor architectures, processor clusters, and the like, which provide high performance computing. The processor 20 may be in electronic communication with the other electronic components of the electronic device 10 through serial or parallel links that include universal busses, address busses, data busses, control lines, and the like. In addition, the processor 20 may include analog to digital converters (ADCs) to convert analog electronic signals to digital data values, or streams of digital data values, and/or digital to analog converters (DACs) to convert digital data values, or streams of digital data values, to analog electronic signals.

The processor 20 is operable, configured, and/or programmed to perform the following functions, operations, processes, methods, and/or algorithms of the electronic device 10 by utilizing hardware, software, firmware, or combinations thereof. Other components, such as the communication element 24 and the memory element 18 may be utilized as well.

The location determining element 22 generally determines a current geolocation of the electronic device 10 and may receive and process radio frequency (RF) wireless signals, such as location wireless signals, output by satellites of a multi-constellation GNSS such as the global positioning system (GPS) utilized in the United States, the GLONASS system utilized in Russia, the Galileo system utilized in Europe, or the like. The location determining element 22 may include satellite navigation receivers, processors, controllers, other computing devices, or combinations thereof, and memory. The location determining element 22 may receive and process a first location signal and/or a second location signal from at least one of the antennas 32, 34, 36 configured as a GNSS antenna. In embodiments, the location determining element 22 may receive and process a first location signal and a second location signal from a diplexer 38 (described in more detail below) that is electrically coupled with antennas 32, 34 and/or 36.

In embodiments, the location determining element 22 may receive a first location signal in a first frequency band and a second location signal in a second frequency band. An exemplary first frequency band is the GPS L5 band with a center frequency of approximately 1176.45 megahertz (MHz) and an exemplary second frequency band is the GPS L1 band with a center frequency of approximately 1575.42 MHz. Alternatively, in embodiments, the first frequency band is the GPS L1 band with a center frequency of approximately 1575.42 MHz and the second frequency band is the GPS L5 band with a center frequency of approximately 1176.45 MHz. In such embodiments, the first location signal includes data and information output by a GPS satellite on the GPS L1 band, which has a center frequency of 1575.42 MHz. The second location signal includes data and information output by a GPS satellite on the GPS L5 band, which has a center frequency of 1176.45 MHz. When the location determining element 22 receives the data and information received on both the GPS L1 band and the GPS L5 band, the location determining element 22 of the current technology determines the current geolocation of the electronic device 10 with greater accuracy than by utilizing data and information received on the GPS L1 band alone.

Although the location determining element 22 of the current technology receives and utilizes data and information received on multiple GPS frequency bands, it is to be understood that the current technology disclosed herein apply to a location determining element 22 configured to receive and utilize data and information from two or more frequency bands associated with other GNSS constellations, such as GLONASS or Galileo, and a location determining element 22 configured to receive and utilize data and information from one or more frequency bands associated with GPS and one or more bands associated with other GNSS constellations, such as GLONASS or Galileo.

It is to be understood that embodiments enabling receipt of location wireless signals in two bands may be applied to other first and second frequency bands. For example, the first frequency band may be the GPS L2 band with a center frequency of approximately 1227 MHz and the second frequency band may be the GPS L1 band with a center frequency of approximately 1575.42 MHz. Similarly, the first frequency band may be the GPS L5 band with a center frequency of approximately 1176.45 MHz and the second frequency band may be the GLONASS L1 band with a center frequency of approximately 1602 MHz. Similarly, the first frequency band may be the GPS L5 band with a center frequency of approximately 1176.45 MHz and the second frequency band may be an Iridium band with a center frequency of approximately 1621.25 MHz. Similarly, the first frequency band may be the GLONASS L2 band with a center frequency of approximately 1246 MHz and the second frequency band may be the GPS L1 band with a center frequency of approximately 1575.42 MHz. Similarly, the first frequency band may be the GLONASS L2 band with a center frequency of approximately 1246 MHz and the second frequency band may be the GLONASS L1 band with a center frequency of approximately 1602 MHz.

In embodiments, the first antenna 32 converts a first location wireless signal output by GPS satellites and having a frequency in the GPS L1 band, which has a center frequency of approximately 1575.42 MHz, into the first location signal. The first antenna 32 also converts a second location wireless signal output by GPS satellites and having a frequency in the GPS L5 band, which has a center frequency of approximately 1175 MHz, into the second location signal. Each of the first location signal and the second location signal includes data and information that the location determining element 22 is able to utilize to determine a current geolocation of the electronic device 10. The location determining element 22 can receive and utilize location wireless signals output by GPS satellites in the GPS L1 band and/or GPS L5 band. With the data and information from location signals output by GPS satellites on both the GPS L1 band and the GPS L5 band, the location determining element 22 of the current technology is capable of determining the current geolocation of the electronic device 10 with greater accuracy than conventional devices that may only utilize location signals output by GPS satellites on the GPS L1 band alone. The location determining element 22 communicates the determined current geolocation to the processor 20, store the determined current geolocation in the memory element 18, or both. Although the location determining element 22 of the current technology utilizes data and information from location wireless signals output on both GPS L1 and L5 bands, it is within the scope of the current technology for the location determining element 22 to utilize data and information from two or more bands from other GNSS constellations, such as GLONASS or Galileo. The location determining element 22 is mounted on the printed circuit board 26.

The communication element 24 processes a first communication electronic signal and a second communication electronic signal that allow the electronic device 10 to communicate wirelessly with other electronic devices and external systems, such as NTN, terrestrial cellular (LTE) networks and Bluetooth™ devices. The communication element 24 may include signal and/or data transmitting and receiving circuits, such as amplifiers, filters, mixers, oscillators, DSPs, modems, systems on a chip, and the like, that process RF electronic signals which include data transmitted and received using various communication standards. The communication element 24 may decode data that has been received in the communication electronic signals for one or more communication protocols and encode data in the communication electronic signals to be transmitted for one or more communication protocols. The communication element 24 processes the first communication electronic signal and the second communication electronic signal.

The first communication electronic signal may have a frequency between approximately 700 MHz and approximately 2200 MHz, which encompasses various cellular (e.g., LTE) bands, the NTN L band and the NTN S band. In embodiments, the communication electronic signal may have a frequency between 1525-1559 MHz (e.g., a resonant frequency of approximately 1542 MHz), which is commonly used by LEO satellites of the NTN for a downlink over the L band (or a frequency between 2180-2200 MHz (e.g., a resonant frequency of approximately 2190 MHz), which is commonly used by LEO satellites of the NTN for a downlink over the S band). Similarly, the communication electronic signal may have a frequency between 1610-1660 MHz (a resonant frequency of approximately 1643 MHz), which is commonly used by LEO satellites of the NTN for a uplink over the L band (or a frequency between 2000-2020 MHz (a resonant frequency of approximately 2010 MHz), which is commonly used by LEO satellites of the NTN for a uplink over the S band).

In embodiments the second communication electronic signal is used to communicate with a terrestrial personal network and has a frequency ranging from approximately 2.4 gigahertz (GHz) to approximately 2.4835 GHz and includes data associated with communication standards such as ANT, ANT+, Bluetooth™, Bluetooth™ low energy (BLE), the industrial, scientific, and medical (ISM) band at 2.4 GHz, or the like. In addition, or instead, the communication electronic signals may include data that is associated with various Institute of Electrical and Electronics Engineers (IEEE) 802.11 Wi-Fi standards operating at 2.4 GHz. Similarly, in embodiments, the second communication electronic signal has a frequency of approximately 5 GHz and includes data associated with various IEEE 802.11 Wi-Fi standards operating at 5 GHz.

The communication element 24 is electrically coupled with the second antenna 34 and the third antenna 36. In embodiments, the second antenna 34 is configured to communicate with a terrestrial cellular network, such as a network that utilizes the one or more LTE bands, and the third antenna 36 is configured to communicate with devices operating at 2.4 GHz, such as Bluetooth™ devices. In other embodiments, the second antenna 34 is configured to communicate with an NTN, which may utilize L bands and/or S bands, and the third antenna 36 is configured to communicate with other electronic devices operating at 2.4 GHz, such as Bluetooth™ devices. In other embodiments, the second antenna 34 is configured to communicate with an NTN, which may utilize NTN L bands and/or NTN S bands, and the third antenna 36 is configured to communicate with a terrestrial cellular network, such as a network that utilizes the one or more LTE bands. When the second antenna 34 and the third antenna 36 are communicating with a terrestrial cellular network, an NTN or other electronic devices operating at 2.4 GHz, the second antenna 34 transmits and/or receives the first communication electronic signal and the third antenna 36 transmits and/or receives the second communication electronic signal. The communication element 24 processes the first communication electronic signal and the second communication electronic signal. The communication element 24 is mounted on the printed circuit board 26.

The printed circuit board 26 retains a plurality of the components of the electronic device 10 and provides electrical connection and electronic communication therebetween. The printed circuit board 26 may be of generally known construction with a first side and an opposing second side. The printed circuit board 26 may also include multiple electrically conductive layers with a top conductive layer placed on the first side, a bottom conductive layer placed on the second side, one or more inner conductive layers positioned between the first and second sides, and an insulating layer between each pair of adjacent conductive layers. The insulating layers may be formed from rigidized or flexible material that includes various combinations of fiberglass, woven glass, matte glass, cotton paper, phenolic cotton paper, polyester, other polymers, epoxies, epoxy resins, and the like. Each electrically conductive layer may include one or more electrically conductive features, such as electronic signal traces, electric power or ground traces, one or more signal, power, or ground pads, integrated circuit package footprints, full or partial power planes, full or partial ground planes, or the like. Also, the electrically conductive features include passive electrical circuit components, such as resistors, capacitors, and inductors. The conductive layers may be formed from metals typically including copper, but also including nickel, aluminum, gold, silver, palladium, zinc, tin, lead, and the like. In addition, the printed circuit board 26 may include plated through hole vias, blind vias, buried vias, and the like. Furthermore, the printed circuit board 26 may include one or more partial or full signal planes and/or one or more signal traces which provide electrical connection, or a signal return path, for the first location signal, the second location signal, the first communication electronic signal, and the second communication electronic signal. As a variety of components are positioned on and electrically coupled through the upper and lower surfaces of the printed circuit board 26, the printed circuit board 26 may have a shape that substantially corresponds to the shape of the housing 12. For instance, as seen in FIG. 2, an electronic device 10 having a substantially round housing 12 may contain within its inner cavity a substantially round printed circuit board 26.

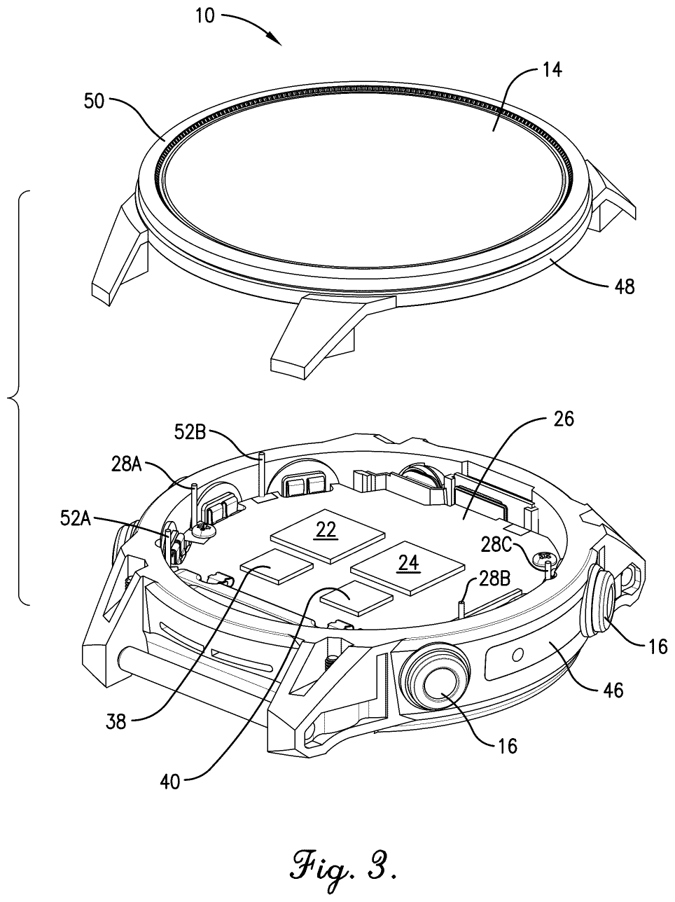

In addition to bezel conductive elements 28, the electronic device 10 comprises a plurality of signal feed bezel conductive elements 52. Each bezel conductive element 28 and signal feed bezel conductive element 52 is formed from electrically conductive materials, such as metals and/or metal alloys, which are electromagnetically radiating. The bezel conductive elements 28 and signal feed bezel conductive elements 52, as shown in FIGS. 3, 7, 8B and 10B, provide an electrical connection from a signal trace, a signal plane, a ground plane, or the like, as applicable, on the printed circuit board 26 to the bezel 50. The bezel conductive elements 28 may be embodied by pins, pogo pins, spring-loaded contacts, conductive clamps, and similar electrical connectors. Each bezel conductive element 28 forms a portion of the first antenna 32 and the third antenna 36, as described in more detail below.

In addition to bottom plate conductive elements 30, the electronic device 10 comprises at least one signal feed bottom plate conductive element 54. Each bottom plate conductive element 30 and the at least one signal feed bottom plate conductive element 54 is formed from electrically conductive materials, such as metals and/or metal alloys, which are electromagnetically radiating. The bottom plate conductive elements 30 and the signal feed bottom plate conductive element 54, as shown in FIGS. 4A, 4B, 7A-7D and 9B, provide an electrical connection from a signal trace, a signal plane, a ground plane, or the like, as applicable, on the printed circuit board 26 to the bottom plate 44. The bottom plate conductive elements 30 may be embodied by pins, pogo pins, spring-loaded contacts, conductive clamps, and similar electrical connectors. Each bottom plate conductive element 30 forms a portion of the second antenna 34, as described in more detail below.

Each antenna 32, 34, 36 converts wireless RF electromagnetic radiation (a wireless signal) at a particular frequency, i.e., a resonant frequency, into a corresponding electronic signal and converts an electronic signal into (or from) a corresponding wireless signal. In embodiments, the wrist-worn electronic device 10 may include additional antennas, such as one or more loop antennas, microstrip antennas, patch antennas, linear antennas, inverted-F antennas, inverted-L antennas, dipole antennas, or the like. It is to be understood that the first antenna 32, the second antenna 34 and the third antenna 36 may each be configured as a slot antenna or a loop antenna. For example, in some embodiments, the first antenna 32, the second antenna 34 and the third antenna 36 are all configured as slot antennas. Similarly, in other embodiments, the first antenna 32, the second antenna 34 and the third antenna 36 are all configured as loop antennas. In some embodiments, the first antenna 32 and the third antenna 36 are configured as slot antennas and the second antenna 34 is configured as a loop antenna.

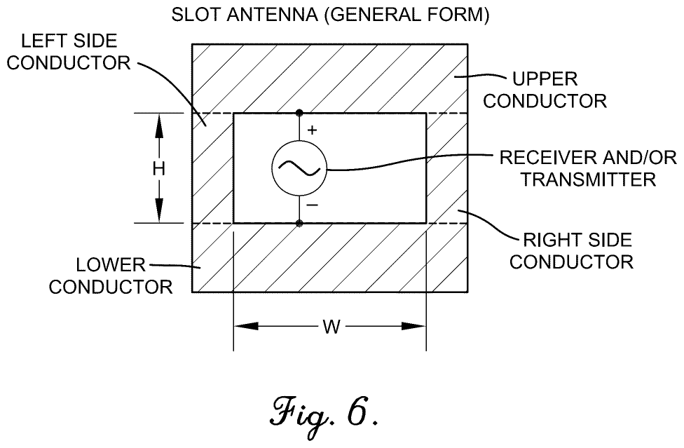

Referring to FIG. 6, a slot antenna, in its general form, includes an electronic signal feed point and an open-centered quadrilateral structure formed from electrically conductive, electromagnetic radiating material, such as metals or metal alloys. The structure of the slot antenna 32, 34, 36 includes an upper conductor, a lower conductor, a left side conductor, and a right side conductor connected to one another to form or create a slot or aperture in the center of the structure. The slot has a height, labeled “H”, and a width, labeled “W”. The perimeter of the slot (i.e., 2H+2W) corresponds to a full wavelength of the frequency of the wireless signal that is to be received and/or transmitted and a width of the upper conductor (W) and the lower conductor (W) corresponds to, or varies according to, a half wavelength of the frequency of that wireless signal. An electronic signal receiver and/or transmitter, such as the location determining element 22 or the communication element 24, is electrically connected to a lower edge of the upper conductor (an upper edge of the slot) and an upper edge of the lower conductor (a lower edge of the slot). An electronic signal is electronically communicated between the electronic signal receiver and/or transmitter and one or more of antennas 32, 34, 36 configured as a slot antenna.

For embodiments in which one or more of antennas 32, 34, 36 of the electronic device 10 are configured as a slot antenna, certain components of the electronic device 10 form the structure of each antenna 32, 34, 36 that surrounds the slot.

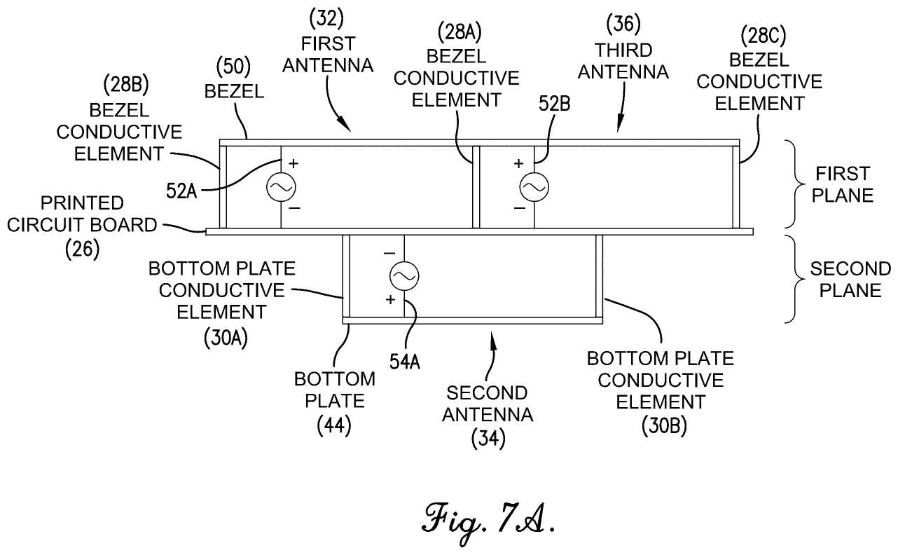

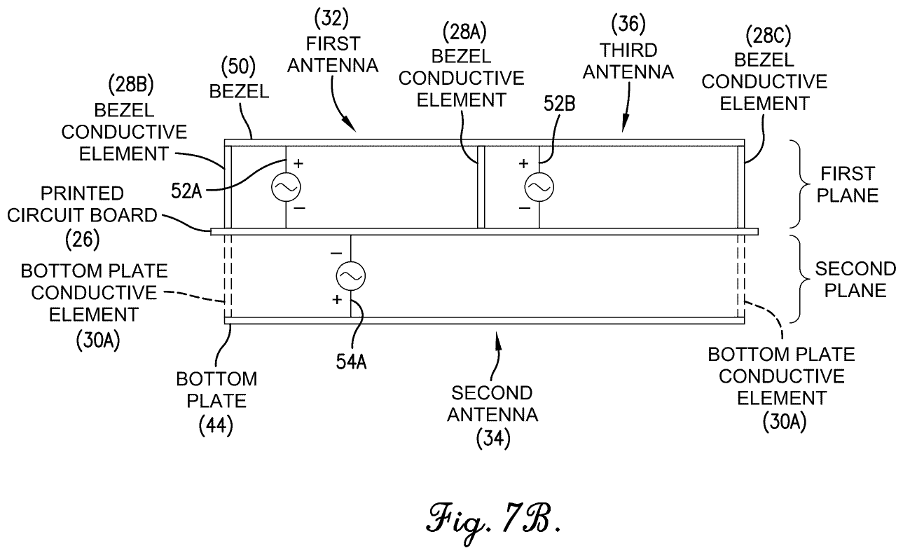

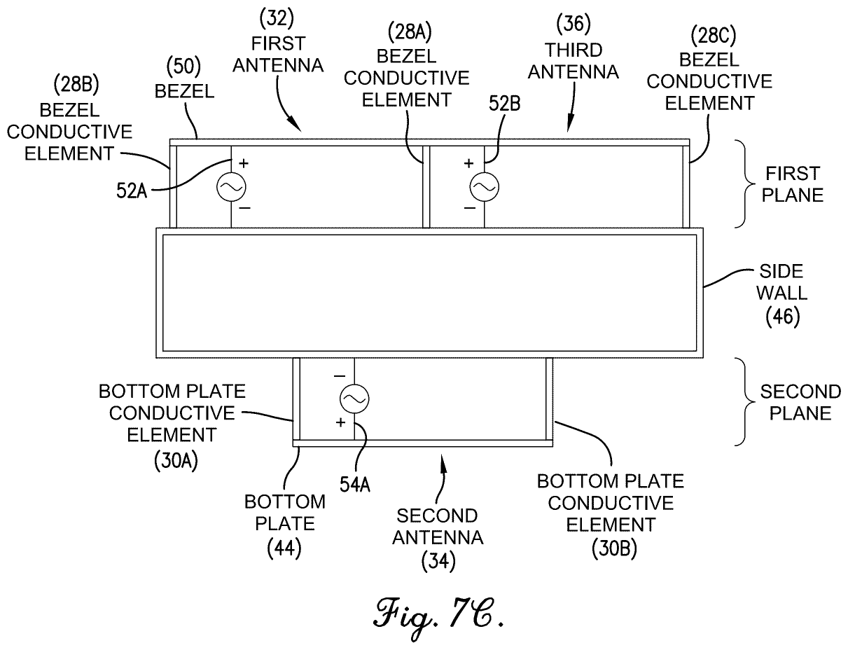

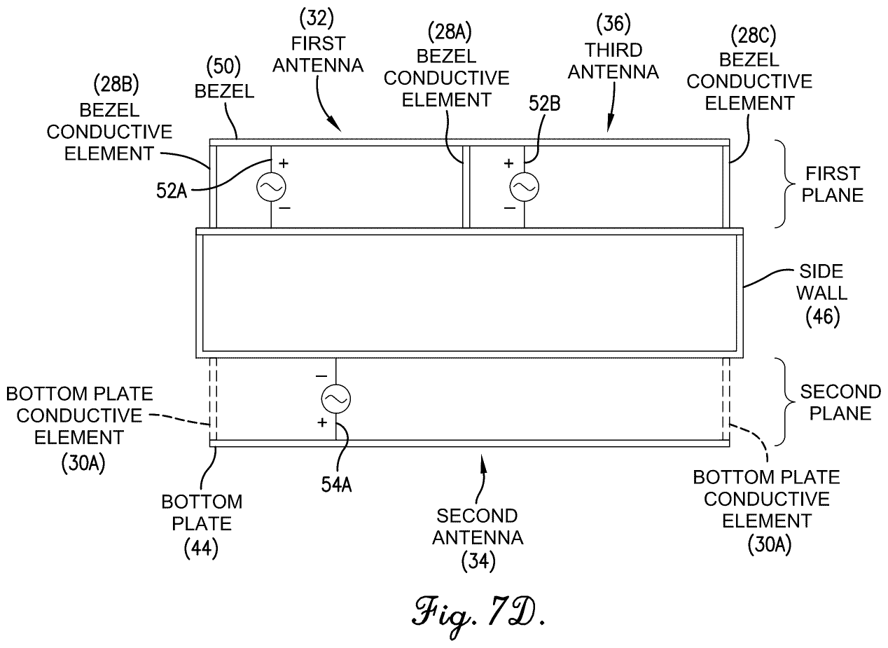

For example, in embodiments, such as shown in FIG. 4A, where the side wall 46 is formed of electrically non-conductive material such as plastic polymers or the like and the first antenna 32, the second antenna 34 and the third antenna 36 are all formed as slot antennas, a portion of the bezel 50 may be utilized to form the upper conductor of the first antenna 32 and the third antenna 36, one or more full or partial conductive planes of the printed circuit board 26 may be utilized to form a portion of the antennas 32, 34, 36 (the upper conductor or the lower conductor, as applicable), and a portion of the bottom plate 44 may be utilized to form the upper conductor of the second antenna 34. The left side and right side conductors of the first antenna 32 and the third antenna 36 may be formed by the bezel conductive elements 28. Similarly, the left side and right side conductors of the second antenna 34 may be formed by the bottom plate conductive elements 30. This utilization of the various components of the electronic device 10 to form the structures of the antennas 32, 34, 36 allows for at least two of the antennas 32, 34, 36 (such as the first antenna 32 and the second antenna 34) to be stacked one on top of the other, or overlap one another, along multiple horizontal planes or levels, as shown in FIG. 7A and FIG. 7B. Accordingly, in such embodiments where the side wall 46 is formed of electrically non-conductive material, the slots corresponding to the first slot antenna 32 and the third slot antenna 36 extend between the bezel 50 and the printed circuit board 26 and the slot corresponding the second slot antenna 34 extends between the bottom plate 44 and the printed circuit board 26.

Alternatively, in embodiments, such as shown in FIG. 4B, where the side wall 46 is formed of electrically conductive material, such as metals and/or metal alloys, which are electromagnetically radiating, and the first antenna 32, the second antenna 34 and the third antenna 36 are all formed as slot antennas, a portion of the bezel 50 may be utilized to form the upper conductor of the first antenna 32 and the third antenna 36, the side wall 46 may be utilized to form a portion (the lower conductor) of the antennas 32, 34, 36, and a portion of the bottom plate 44 may be utilized to form the upper conductor of the second antenna 34. The left side and right side conductors of the first antenna 32 and the third antenna 36 may be formed by the bezel conductive elements 28 extending between the bezel 50 and an upper surface of the side wall 46. Similarly, the left side and right side conductors of the second antenna 34 may be formed by the bottom plate conductive elements 30 extending between the bottom plate 44 and a lower surface of the side wall 46. This utilization of the various components of the electronic device 10 to form the structures of the antennas 32, 34, 36 allows for at least two of the antennas 32, 34, 36 (such as the first antenna 32 and the second antenna 34) to be stacked one on top of the other, or overlap one another, along multiple horizontal planes or levels, as shown in FIG. 7C and FIG. 7D, which are not drawn to scale. Accordingly, in such embodiments where the side wall 46 is formed of electrically conductive material, the slots corresponding to the first slot antenna 32 and the third slot antenna 36 extend between the bezel 50 and the upper surface of the side wall 46, which are separated by the bezel retainer 48 formed from an electrically non-conductive material, and the slot corresponding the second slot antenna 34 extends between the lower surface of the side wall 46 and the printed circuit board 26, which are separated by the lower ring 62 formed from an electrically non-conductive material.

In embodiments, the electronic device 10 includes a substantially cylindrical structure formed of electrically non-conductive material, such as plastic polymers or the like, having an outward protrusion (lip) forming each of the bezel retainer 48 and the lower ring 62. In such embodiments, the side wall 46 formed of electrically conductive material, such as metals and/or metal alloys, is positioned over the substantially cylindrical structure. Similarly, the bezel 50 and the bottom plate 44 are formed of electrically conductive material and are positioned over and below the substantially cylindrical structure, respectively. Accordingly, in such embodiments, the bezel retainer 48 and the lower ring 62 are vertically opposing portions of the substantially cylindrical structure formed of electrically non-conductive material.

In embodiments, a bezel conductive element 28A and a bezel conductive element 28B associated with the first antenna 32 may contact bezel 50 at positions relative to a first signal feed bezel conductive element 52A to form a slot and the bezel conductive element 28A and a bezel conductive element 28C associated with the second antenna 32 may contact bezel 50 at positions relative to a second signal feed bezel conductive element 52B to form another slot. Portions of the bezel 50 not forming the upper conductor of the first antenna 32 or the second antenna 36 are electrically grounded. In embodiments, the lower conductor of the second antenna 34 is formed by a portion of the circumference of the bottom plate 44, as shown in FIGS. 7A and 7C. Portions of the bottom plate 44 not forming the lower conductor of the second antenna 34 are electrically grounded.

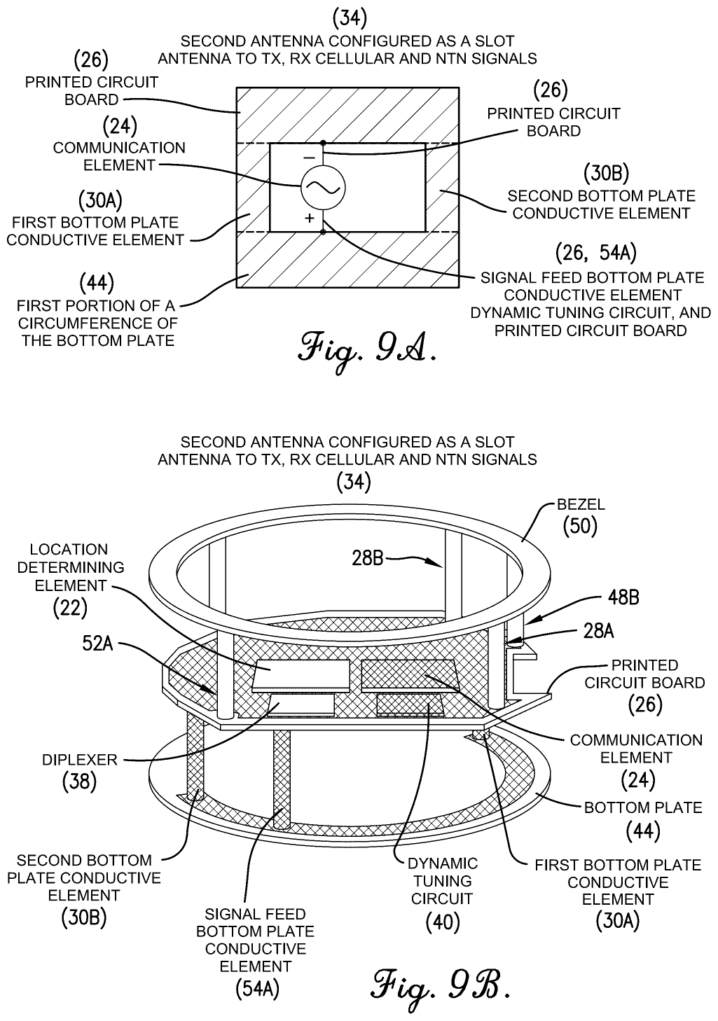

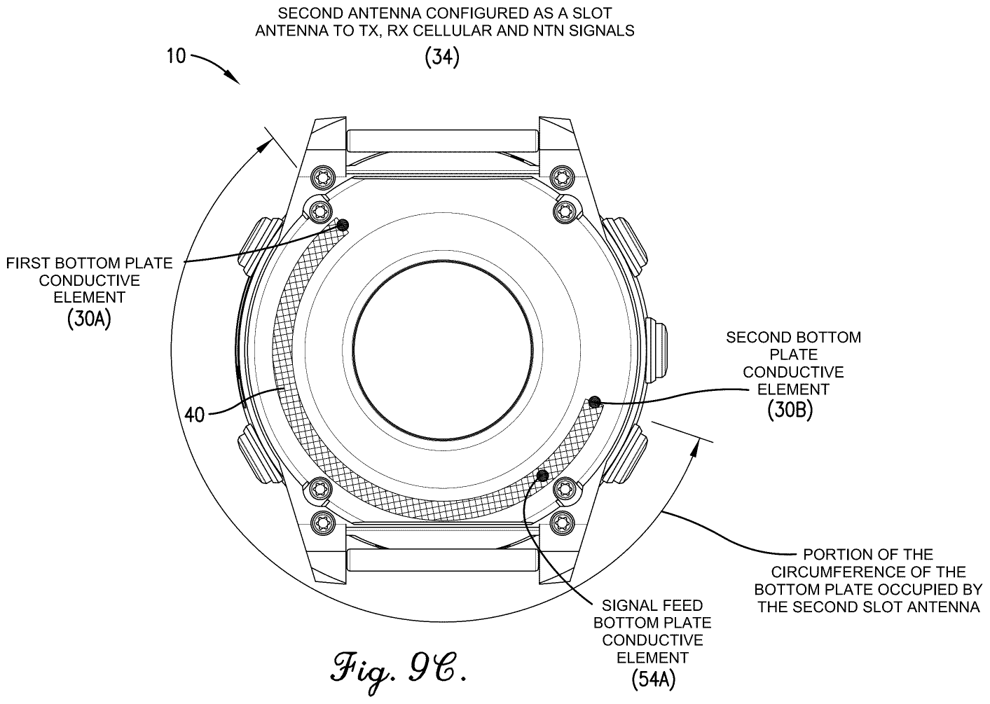

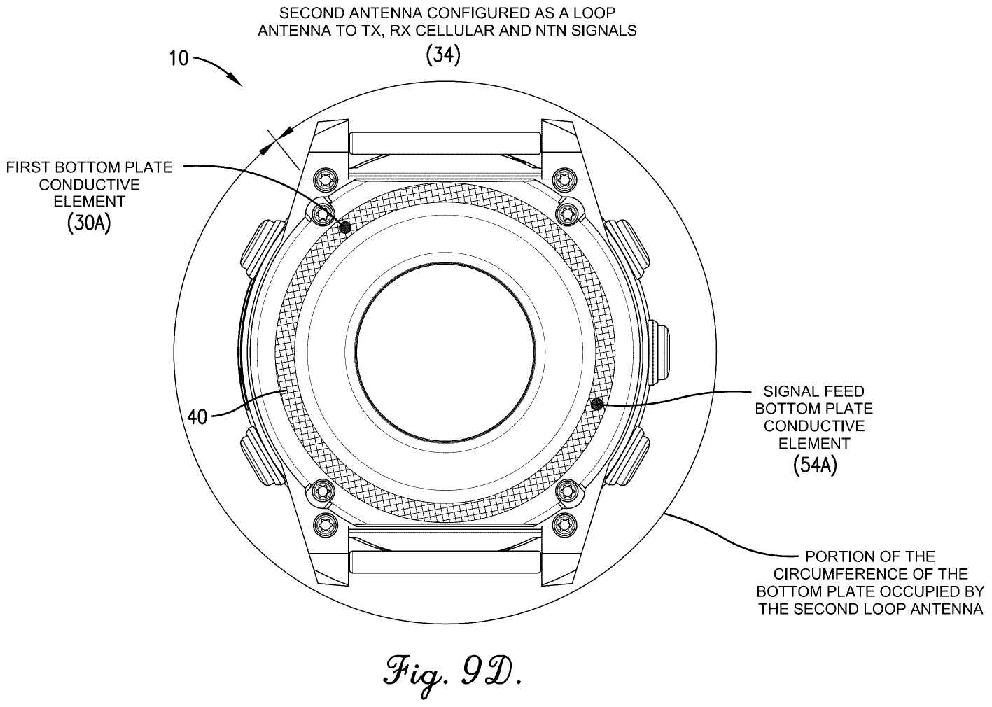

For embodiments in which one or more of antennas 32, 34, 36 of the electronic device 10 are configured as a loop antenna, certain components of the electronic device 10 form the structure of each antenna 32, 34, 36 that form the loop. For example, in embodiments where the first antenna 32 and the second antenna 34 are formed as slot antennas and the third antenna 36 is formed as loop antenna, a portion of the bezel 50 may be utilized to form a portion of the first antenna 32 and the third antenna 36, a portion of the bottom plate 44 may be utilized to form a portion of the second antenna 34. The first antenna 32 and the third antenna 36 are each also formed by a bezel conductive element 28 and the first signal feed bezel conductive element 52A or the second signal feed bezel conductive element 52B, respectively. Similarly, the second antenna is also formed by a bottom conductive element 30 and the signal feed bottom plate conductive element 54A. In embodiments, as shown in FIGS. 7B and 7D, the lower conductor of the second antenna 34 is formed by the circumference of the bottom plate 44. FIGS. 7B and 7D correspond to the embodiment depicted in FIG. 9D in which the bottom plate conductive element 30A may contact bottom plate 44 at a position that is substantially opposite to a position on bottom plate 44 that is contacted by a signal feed bottom plate conductive element 54A such that the circumference of the bottom plate 44 is associated with the second antenna 34.

It is to be understood that each of the first antenna 32, the second antenna 34 and the third antenna 36 may be configured as a slot antenna or a loop antenna.

Furthermore, it is to be understood that each antenna 32, 34, 36 can be configured to perform any of the wireless signal transmission and reception functions of the electronic device 10 described herein. That is, any of the antennas 32, 34, 36 can be configured to wirelessly receive the GPS L1 band location signal, any of the antennas 32, 34, 36 can be configured to wirelessly receive the GPS L5 band location signal, and any one or more of the antennas 32, 34, 36 can be configured to wirelessly communicate with (transmit electronic signals to and receive electronic signals from) an NTN, a terrestrial cellular (e.g., LTE) network or other electronic devices using common wireless communication protocols to communicate with a terrestrial personal network, such as Wi-Fi or Bluetooth™. Specific configurations or implementations of the antennas 32, 34, 36 for the wireless signal functions are described as follows.

In embodiments, the first antenna 32 is configured to receive at least one location signal having a frequency corresponding to the GPS L1 band and/or the GPS L5 band. For example, in some embodiments, the first antenna 32 is configured to receive a first location signal having a frequency corresponding to the GPS L1 band, which has a center frequency of 1575.42 MHz. Similarly, in other embodiments, the first antenna 32 is configured to receive a first location signal having a frequency corresponding to the GPS L5 band, which has a center frequency of 1176.45 MHz. In some embodiments, the first antenna 32 is configured to receive a first location signal having a frequency corresponding to the GPS L1 band that has a center frequency of 1575.42 MHz, and a second location signal having a frequency corresponding to the GPS L5 band, which has a center frequency of 1176.45 MHz. In such embodiments, the diplexer 38 may be configured to receive a composite (combined) first location signal and second location signal from the first antenna 32 and separate the first location signal from the second location signal. The diplexer 38 may be electrically coupled with the location determining element 22 and separately output the first location signal and the second location signal to the location determining element 22.

In embodiments where the first antenna 32 receives location signals in the GPS L1 band, a first portion of the circumference of the bezel 50 associated with the first antenna 32 and the corresponding portion (perimeter) of the printed circuit board 26 between the bezel conductive elements 28A, 28B may each have a width that corresponds to roughly one-half of the wavelength of the center frequency of the GPS L1 band. Similarly, in embodiments where the first antenna 32 receives location signals in the GPS L5 band, a first portion of the circumference of the bezel 50 associated with the first antenna 32 and the corresponding portion (perimeter) of the printed circuit board 26 between the bezel conductive elements 28A, 28B may each have a width that corresponds to roughly one-half of the wavelength of the center frequency of the GPS L5 band. In embodiments where the first antenna 32 receives location signals in the GPS L1 band and the GPS L5 band, a first portion of the circumference of the bezel 50 associated with the first antenna 32 and the corresponding portion (perimeter) of the printed circuit board 26 between the bezel conductive elements 28A, 28B may each have a width that corresponds to roughly one-half of the wavelength of a first resonant frequency corresponding to the frequency of the GPS L1 band and a second resonant frequency corresponding to the frequency of the GPS L5 band. The first antenna 32 converts the first location wireless signal (corresponding to the GPS L1 band signal) and the second location wireless signal (corresponding to the GPS L5 band signal) to a location signal that includes the frequency components of, and the information of, both the first location wireless signal and the second location wireless signal.

In embodiments, the second antenna 34 is configured to wirelessly communicate with (transmit communication electronic signals to and receive communication electronic signals from) an NTN and/or a terrestrial network. A first portion of the circumference of the bottom plate 44 associated with the second antenna 34 and the corresponding portion (perimeter) of the printed circuit board 26 between the bottom plate conductive elements 30A, 30B may each have a width that corresponds to a frequency associated with the wireless signals transmitted to or received by the electronic device 10. For instance, the second antenna 34 may have an effective length of approximately one-half of the wavelength of a frequency associated with the wireless signals transmitted to or received from the NTN and/or the terrestrial network, such as a cellular (e.g., LTE) network. The second antenna 34 may transmit or receive wireless signals having a frequency between approximately 700 MHz to approximately 2200 MHz. The second antenna 34 converts the first communication wireless signal into the first communication electronic signal, wherein the first communication electronic signal includes the information of the first communication wireless signal. The second antenna 34 converts the first communication electronic signal into the first communication wireless signal, wherein the first communication wireless signal includes the information of the first communication electronic signal.

In some embodiments, the third antenna 36 is configured to wirelessly communicate with (transmit communication electronic signals to and receive communication electronic signals from) a terrestrial personal network using common wireless communication protocols, such as Wi-Fi or Bluetooth™. The transmission and receipt of wireless communication signals may utilize frequencies of approximately 2.4 GHz for Bluetooth™ and/or Wi-Fi communications. A second portion of the circumference of the bezel 50 associated with the third antenna 36 and the corresponding portion (perimeter) of the printed circuit board 26 between the bezel conductive elements 28A, 28C may each have a width that corresponds to a frequency of the wireless communication signals, such as 2.4 GHz or 5 GHz. For instance, the third antenna 36 may have an effective length of approximately one-half of the wavelength of 2.4 GHz or 5 GHz. The third antenna 36 converts the second communication wireless signal into the second communication electronic signal, wherein the second communication electronic signal includes the information of the second communication wireless signal. The third antenna 36 converts the second communication electronic signal into the second communication wireless signal, wherein the second communication wireless signal includes the information of the second communication electronic signal. In other embodiments, the third antenna 36 is configured to wirelessly communicate with (transmit communication electronic signals to and receive communication electronic signals from) an NTN or a terrestrial network. In such embodiments, a second portion of the circumference of the bezel 50 associated with the third antenna 36 and the corresponding portion (perimeter) of the printed circuit board 26 between the bezel conductive elements 28A, 28C may each have a width that corresponds to a frequency associated with the wireless signals transmitted or received by the NTN and/or terrestrial cellular (e.g., LTE) networks. For instance, the third antenna 36 may have an effective length of approximately one-half of the wavelength of a frequency associated with the wireless signals transmitted to or received from the NTN and/or the terrestrial network, such as a cellular (e.g., LTE) network.

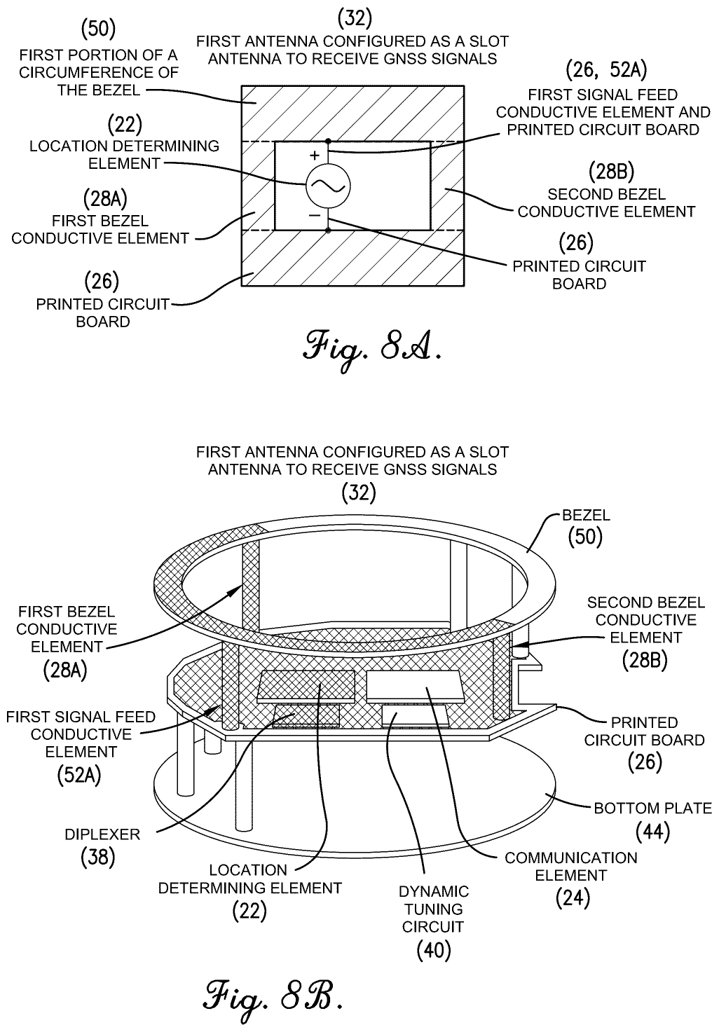

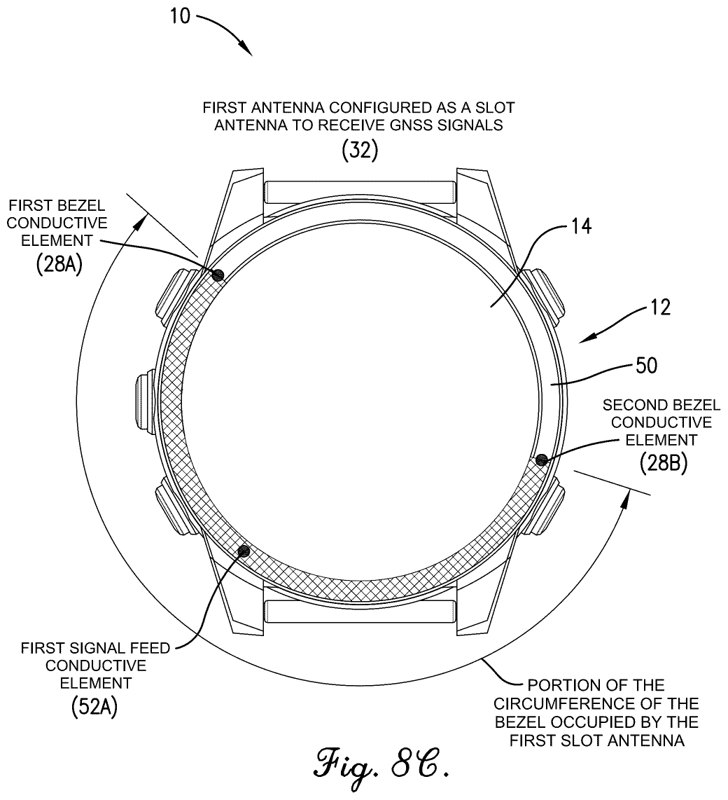

Referring to FIGS. 8A, 8B, and 8C, the first antenna 32 may be a slot antenna configured as a GNSS wireless signal antenna, which receives wireless location signals in the GPS L1 band of frequencies, centered at approximately 1575.42 MHz, and/or the GPS L5 band of frequencies, centered at approximately 1175 MHz. Given that the L band is generally defined as including any wireless signals between the frequencies of 1000 MHz and 2000 MHz, the first antenna 32 may also receive and transmit wireless signals in at least part of the frequency range for the NTN L band. The structure of the first antenna 32 is formed by the following components of the electronic device 10. The upper conductor of the first antenna 32 is formed by a first portion of a circumference of the bezel 50, as shown in FIGS. 8B and 8C, extending in a clockwise (CW) direction from approximately 4:00 to 10:00.

In embodiments, such as shown in FIG. 4A, where the side walls 46 are formed of an electrically non-conductive material, such as metals and/or metal alloys, the lower conductor of the first antenna 32 is formed by the printed circuit board 26. The left side conductor of the first antenna 32 is formed by a first bezel conductive element 28A, which provides an electrical ground or common electronic signal path for the first antenna 32 and the third antenna 36. The right side conductor of the first antenna 32 is formed by a second bezel conductive element 28B, which provides an electrical ground or common electronic signal path for the first antenna 32 only. The electronic signal receiver is the location determining element 22, which is electrically connected to the structure of the first antenna 32 through the one or more signal traces of the printed circuit board 26 and the first signal feed bezel conductive element 52A, which provides a signal feed path for the first and second location signals. Through the signal feed bezel conductive element 52A and various signal traces or conductive planes on the printed circuit board 26, the first and second location signals are electronically communicated between the first antenna 32 and the diplexer 38. The portions of the bezel 50 and the printed circuit board 26 that are associated with the first antenna 32 are shown in crosshatch in FIGS. 8B and 8C.

In embodiments, such as shown in FIG. 4B, where the side walls 46 are formed of an electrically conductive material, the lower conductor of the first antenna 32 is formed by an upper surface of the side walls 46. Similar to the view shown in FIG. 8B where a portion of the printed circuit board 26 forms the bottom conductor of the first antenna 32, the upper conductor of the first antenna 32 is formed by a first portion of a circumference of the bezel 50 and extends in a clockwise (CW) direction from approximately 4:00 to 10:00. The left side conductor of the first antenna 32 is formed by a first bezel conductive element 28A, which extends between the upper surface of side wall 46 and a lower surface of the bezel 50 and provides an electrical ground or common electronic signal path for the first antenna 32 and the third antenna 36. The right side conductor of the first antenna 32 is formed by a second bezel conductive element 28B, which extends between the upper surface of side wall 46 and the lower surface of the bezel 50 and provides an electrical ground or common electronic signal path for the first antenna 32 only. The electronic signal receiver is the location determining element 22, which is electrically connected to the structure of the first antenna 32 through the one or more signal traces of the printed circuit board 26 and the first signal feed bezel conductive element 52A, which is attached to the printed circuit board 26 at a terminal, contacts the bezel 50 at a signal feed point and provides a signal feed path for the first and second location signals. Through the signal feed bezel conductive element 52A and various signal traces or conductive planes on the printed circuit board 26, the first and second location signals are electronically communicated between the first antenna 32 and the diplexer 38. Similar to the embodiments where the side walls 46 are formed of electrically non-conductive material, the portions of the bezel 50 and the printed circuit board 26 that are associated with the first antenna 32 are shown in crosshatch in FIG. 8C.

Referring to FIGS. 9A, 9B, and 9C, the second antenna 34 may be configured to communicate with terrestrial networks and NTN. The second antenna 34 is configured to transmit and receive wireless communication signals utilizing various frequency bands that are at least partially used by both a cellular network and a NTN. In embodiments, the second antenna 34 may receive wireless signals in a frequency range between approximately 700 MHz to approximately 2200 MHz and the frequency may be dynamically selected by the dynamic tuning circuit 40B. For example, in embodiments, the second antenna 34 may be configured to communicate with an LEO satellite of the NTN over a 1525-1660 MHz band to support uplink and downlink frequencies for the NTN L band. Similarly, in other embodiments, the second antenna 34 may be configured to communicate with an LEO satellite of the NTN over a 1980-2200 MHz band to support uplink and downlink frequencies for the NTN S band. As another example, the second antenna 34 may be configured to communicate with a terrestrial cellular (e.g., LTE) network using frequency bands utilized by the cellular network, such as the B bands (e.g., B1, B2, B3, B4, B8, B12, B20, B28, etc.) that are utilized in North America, Central America, South America, Europe, the Middle East, Africa, Asia, Australia, and New Zealand.

When formed as a slot antenna, the structure of the second antenna 34 may include the following components of the electronic device 10. In embodiments where the side walls 46 are formed of an electrically non-conductive material, such as shown in FIG. 4A, the bottom conductor of the second antenna 34 is formed by one of the full or partial signal or ground planes of the printed circuit board 26. The bottom conductor of the second antenna 34 is formed by a first portion of a circumference of the bottom plate 44, as shown in FIGS. 9B and 9C. For the view shown in FIG. 9B, which depicts an upper surface of the bottom plate 44, the first portion of the circumference of the bottom plate 44 extends in a clockwise (CW) direction from approximately 1:00 to 8:00. For the view shown in FIG. 9C, which depicts a lower surface of the bottom plate 44, the first portion of the circumference of the bottom plate 44 extends in a clockwise (CW) direction from approximately 4:00 to 11:00. The left side conductor of the second antenna 34 is formed by the first bottom plate conductive element 30A, which provides an electrical ground or common electronic signal path for the second antenna 34 only. The right side conductor of the second antenna 34 is formed by the second bottom plate conductive element 30B, which provides an electrical ground or common electronic signal path for the second antenna 34 only. The upper conductor of the second antenna 34 is formed by a first portion of the circumference of the bottom plate 44, as shown in FIGS. 9B and 9C. As shown by the polarity markings provided in FIGS. 7 and 9A, the “upper” conductor for the second antenna 34, which is positioned below the printed circuit board 26, is formed by the bottom plate 44, which is functionally equivalent to the bezel 50 for the first antenna 32 as it corresponds to the positive (+) polarity of the signal source shown in the general form of a slot antenna depicted in FIG. 6. In these embodiments, the “lower” conductor for the second antenna 34 is the printed circuit board 26, which corresponds to the negative (−) polarity of the signal source shown in the general form of a slot antenna depicted in FIG. 6. The electronic signal transmitter and receiver is the communication element 24, which is electrically connected to the structure of the second antenna 34 through the one or more signal traces of the printed circuit board 26 and the signal feed bottom plate conductive element 54A, which provides a signal feed path for the first communication electronic signal. Through the signal feed bottom plate conductive element 54A and various signal traces or conductive planes on the printed circuit board 26, the first communication electronic signal is electronically communicated between the second antenna 34 and the communication element 24. The portions of the bottom plate 44 and the printed circuit board 26 that are associated with the second antenna 34 are shown in crosshatch in FIGS. 9B and 9C.

In embodiments where the side walls 46 are formed of an electrically conductive materials, such as metals and/or metal alloys, such as shown in FIG. 4B, the bottom conductor of the second antenna 34 is formed by a bottom surface of the side walls 46. The upper conductor of the second antenna 34 is formed by a first portion of a circumference of the bottom plate 44, as shown in FIG. 9C. Similar to the view shown in FIG. 9B where a portion of the printed circuit board 26 forms the bottom conductor of the second antenna 34, the first portion of the circumference of the bottom plate 44 extends in a clockwise (CW) direction from approximately 1:00 to 8:00, and for the view shown in FIG. 9C, which depicts a lower surface of the bottom plate 44, the first portion of the circumference of the bottom plate 44 extends in a clockwise (CW) direction from approximately 4:00 to 11:00. The left side conductor of the second antenna 34 is formed by the first bottom plate conductive element 30A, which extends between the lower surface of side wall 46 and the bottom plate 44 and provides an electrical ground or common electronic signal path for the second antenna 34 only. The right side conductor of the second antenna 34 is formed by the second bottom plate conductive element 30B, which extends between the lower surface of side wall 46 and the bottom plate 44 and provides an electrical ground or common electronic signal path for the second antenna 34 only. The upper conductor of the second antenna 34 is formed by a first portion of the circumference of the bottom plate 44 corresponding to the first portion of the circumference of the bottom plate 44. As shown by the polarity markings provided in FIGS. 7 and 9A, the “upper” conductor for the second antenna 34, which is positioned below the printed circuit board 26, is formed by the bottom plate 44, which is functionally equivalent to the bezel 50 for the first antenna 32 as it corresponds to the positive (+) polarity of the signal source shown in the general form of a slot antenna depicted in FIG. 6. In these embodiments, the “lower” conductor for the second antenna 34 is the bottom surface of side walls 46, which corresponds to the negative (−) polarity of the signal source shown in the general form of a slot antenna depicted in FIG. 6. The electronic signal transmitter and receiver is the communication element 24, which is electrically connected to the structure of the second antenna 34 through the one or more signal traces of the printed circuit board 26 and the signal feed bottom plate conductive element 54A, which is attached to the printed circuit board 26 at a terminal, contacts the bottom plate 44 at a signal feed point and provides a signal feed path for the first communication electronic signal. Through the signal feed bottom plate conductive element 54A and various signal traces or conductive planes on the printed circuit board 26, the first communication electronic signal is electronically communicated between the second antenna 34 and the communication element 24. Similar to the embodiments where the side walls 46 are formed of electrically non-conductive material, the portions of the bottom plate 44 and the side walls 46 that are associated with the second antenna 34 are shown in crosshatch in FIG. 9C.

Referring to FIG. 9D, which relates to an embodiment in which the second antenna 34 is a loop antenna configured to communicate with terrestrial networks and NTN, the signal feed bottom plate conductive element 54A is electrically connected to the communication element 24 through the one or more signal traces of the printed circuit board 26 and the signal feed bottom plate conductive element 54A, which provides a signal feed path for the first communication electronic signal. Portions of the bottom plate 44 that are associated with the second antenna 34 are shown in crosshatch in FIG. 9D.

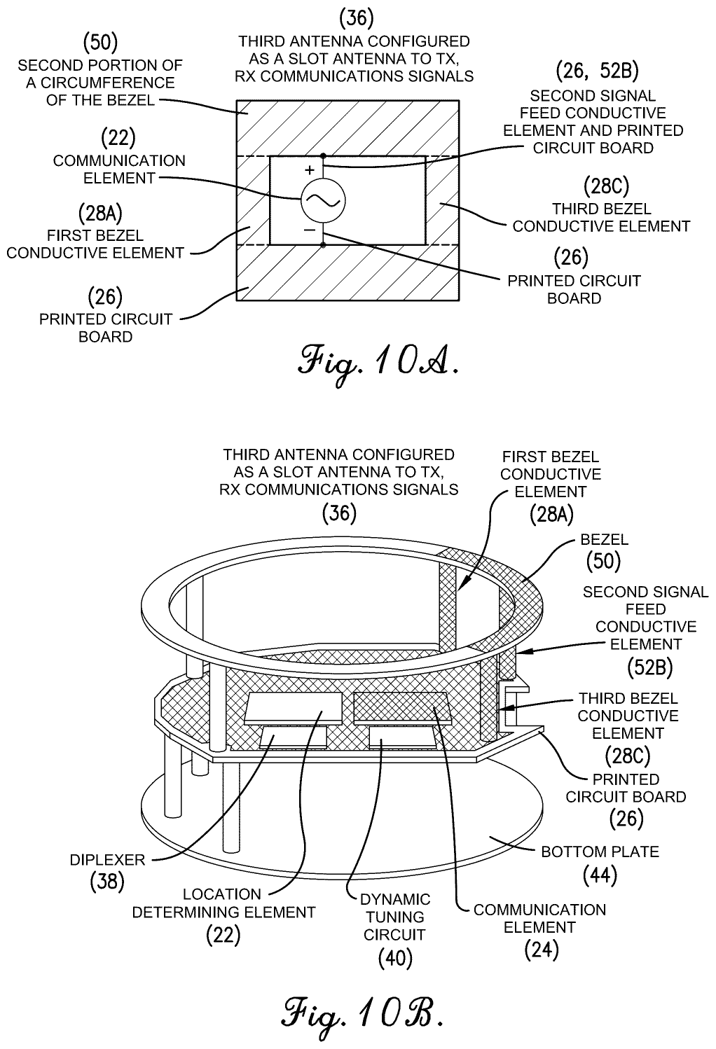

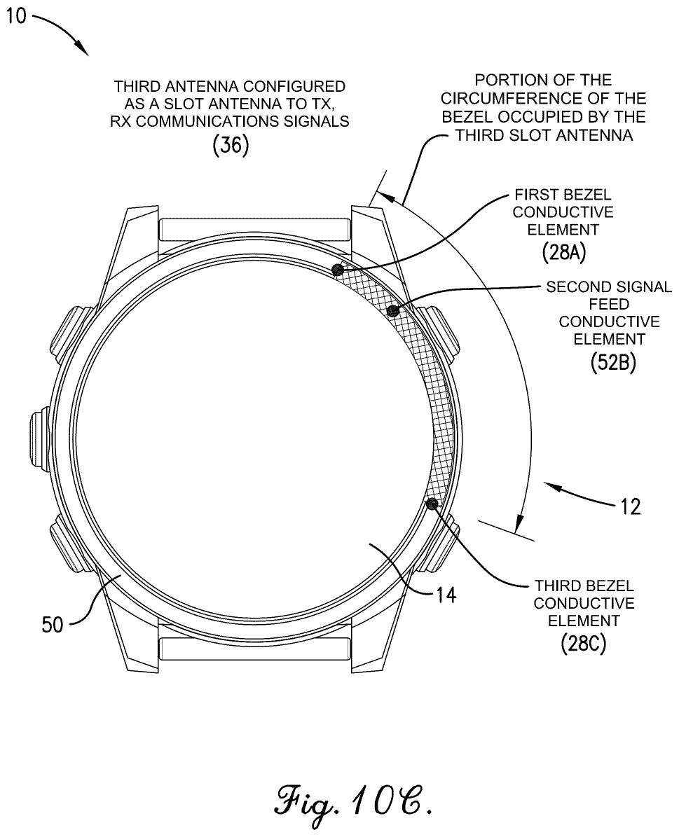

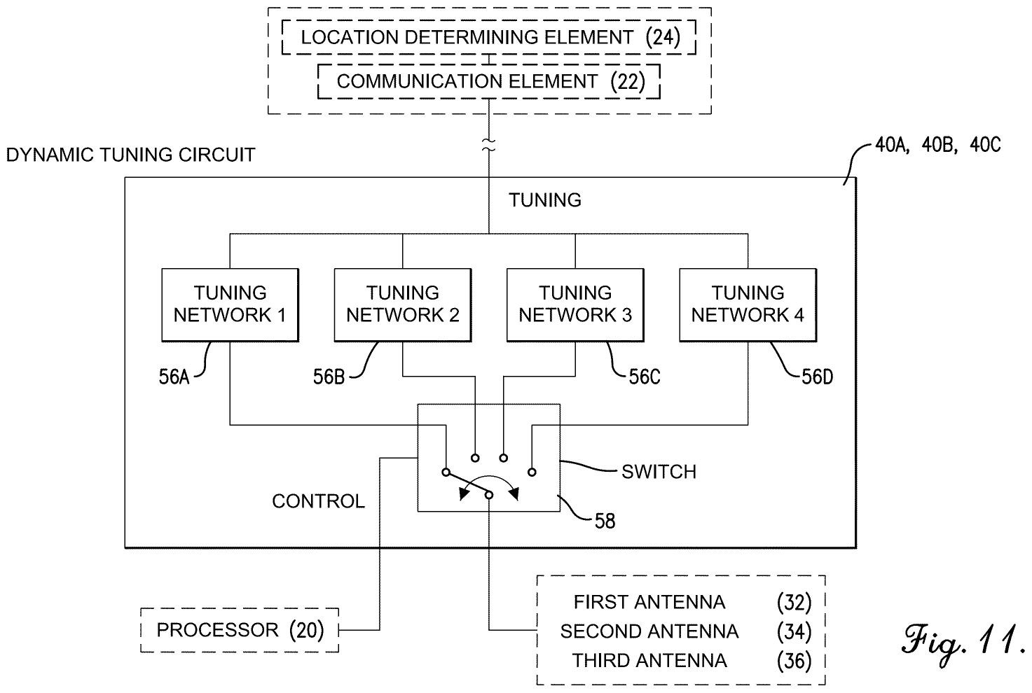

Referring to FIGS. 10A, 10B, and 10C, in embodiments, the third antenna 36 may communicate with a terrestrial personal network, such as a Wi-Fi or a Bluetooth™ connection. In such embodiments, the third antenna 36 transmits and receives Bluetooth™ and/or Wi-Fi having frequencies of approximately 2.4 GHz. The structure of the third antenna 36 is formed by the following components of the electronic device 10. The upper conductor of the third antenna 36 is formed by a second portion of the circumference of the bezel 50, as shown in FIGS. 10B and 10C, extending in a clockwise (CW) direction from approximately 1:00 to 4:00.

In embodiments, such as shown in FIG. 4A, where the side walls 46 are formed of an electrically non-conductive material, such as metals and/or metal alloys, the lower conductor of the third antenna 36 is formed by one of the full or partial signal or ground planes of the printed circuit board 26. The left side conductor of the third antenna 36 is formed by the first bezel conductive element 28A, which provides an electrical ground or common electronic signal path for the first antenna 32 and the third antenna 36. The right side conductor of the third antenna 36 is formed by a third bezel conductive element 28C, which provides an electrical ground or common electronic signal path for the first antenna 32 (and, in embodiments, the third antenna 36). The electronic signal receiver is the communication element 24, which is electrically connected to the structure of the third antenna 36 through the one or more signal traces of the printed circuit board 26 and the second signal feed bezel conductive element 52B, which provides a signal feed path for the second communication electronic signal. Through the second signal feed bezel conductive element 52B and various signal traces or conductive planes on the printed circuit board 26, the second communication electronic signal is electronically communicated between the third antenna 36 and the communication element 24. The portions of the bezel 50 and the printed circuit board 26 that are associated with the third antenna 36 are shown in crosshatch in FIGS. 10B and 10C.

In embodiments, such as shown in FIG. 4B, where the side walls 46 are formed of an electrically conductive material, the lower conductor of the third antenna 36 is formed by an upper surface of the side walls 46. Similar to the view shown in FIG. 10B where a portion of the printed circuit board 26 forms the bottom conductor of the third antenna 36, the upper conductor of the third antenna 36 is formed by a second portion of the circumference of the bezel 50 and extends in a clockwise (CW) direction from approximately 1:00 to 4:00. The left side conductor of the third antenna 36 is formed by the first bezel conductive element 28A, which extends between the upper surface of side wall 46 and a lower surface of the bezel 50 and provides an electrical ground or common electronic signal path for the first antenna 32 and the third antenna 36. The right side conductor of the third antenna 36 is formed by a third bezel conductive element 28C, which extends between the upper surface of side wall 46 and a lower surface of the bezel 50 and provides an electrical ground or common electronic signal path for the first antenna 32 (and, in embodiments, the third antenna 36). The electronic signal receiver is the communication element 24, which is electrically connected to the structure of the third antenna 36 through the one or more signal traces of the printed circuit board 26 and the second signal feed bezel conductive element 52B, which is attached to the printed circuit board 26 at a terminal, contacts the bezel 50 at a signal feed point and provides a signal feed path for the second communication electronic signal. Through the second signal feed bezel conductive element 52B and various signal traces or conductive planes on the printed circuit board 26, the second communication electronic signal is electronically communicated between the third antenna 36 and the communication element 24. Similar to the embodiments where the side walls 46 are formed of electrically non-conductive material, the portions of the bezel 50 and the printed circuit board 26 that are associated with the third antenna 36 are shown in crosshatch in FIG. 10C.

The implementation of the antennas 32, 34, 36 as depicted in FIGS. 8B, 9B, and 10B is merely exemplary. The positioning of the bezel conductive elements 28A, 28B, 28C and signal feed bezel conductive elements 52A, 52B along the circumference of the bezel 50 and the positioning of the bottom plate conductive elements 30A, 30B and signal feed bottom plate conductive element 54A along the circumference of the bottom plate 44 are dependent on, and vary according to, the spacing between the printed circuit board 26 and the bezel 50 and the spacing between the printed circuit board 26 and the bottom plate 44. Typically, the spacing between the bottom plate 44 and the bezel 50 is fixed. However, it is possible for the printed circuit board 26 to be repositioned vertically relative to the bottom plate 44 and the bezel 50. In such a situation, the positioning of the bezel conductive elements 28A, 28B, 28C along the circumference of the bezel 50 and the positioning of the bottom plate conductive elements 30A, 30B along the circumference of the bottom plate 44 would change in order to maintain the same perimeter of the slot opening of each antenna 32, 34, 36. For example, if the printed circuit board 26 were to be positioned closer to the bezel 50 and farther from the bottom plate 44, then the height of the first antenna 32 and the third antenna 36 would decrease, and the height of the second antenna 34 would increase. Accordingly, the bezel conductive elements 28A, 28B that form the left and right side conductors of the first antenna 32 would be moved farther apart along the circumference of the bezel 50 in order to increase the width of the slot opening of the first antenna 32. The bezel conductive elements 28A, 28C that form the left and right side conductors of the third antenna 36 would be moved farther apart along the circumference of the bezel 50 in order to increase the width of the slot opening of the third antenna 36. In addition, the bottom plate conductive elements 30A, 30B that form the left and right side conductors of the second antenna 34 would be moved closer together along the circumference of the bottom plate 44 in order to decrease the width of the slot opening of the second antenna 34.

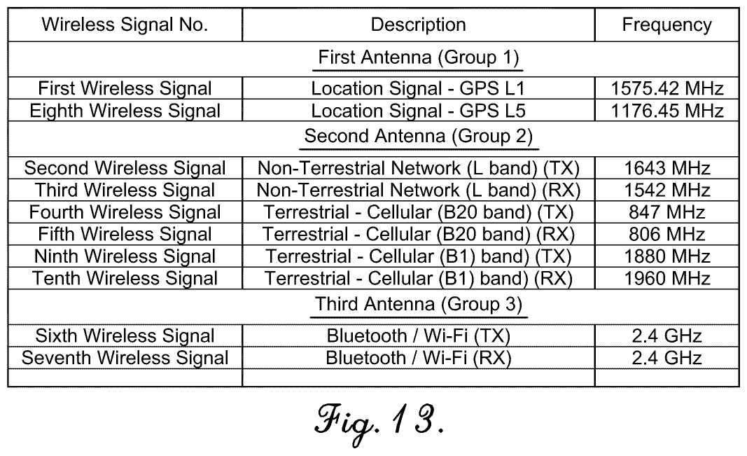

As shown in FIG. 13, in embodiments, the first antenna 32 may be formed in part by the bezel 50 and is configured to receive a first wireless signal, which is a first location signal (GPS L1), having a first frequency of 1575.42 MHz, as well as an eighth wireless signal, which is a second location signal (GPS L5), having an eighth frequency of 1176.45 MHz. A first frequency group is formed by the first frequency and the eighth frequency. The second antenna 34 may be formed in part by the bottom plate 44 and is configured to transmit a second wireless signal having a frequency of 1643 MHz to a non-terrestrial network (NTN L band) and receive a third wireless signal having a frequency of 1542 MHz from the non-terrestrial network (NTN L band). In embodiments, the second antenna 34 is also configured to transmit a fourth wireless signal having a frequency of 847 MHz to a terrestrial cellular network (using the B20 band) and receive a fifth wireless signal having a frequency of 806 MHz from the terrestrial cellular network (using the B20 band). Similarly, in embodiments, the second antenna 34 is also configured to transmit a ninth wireless signal having a frequency of 1880 MHz to a terrestrial cellular network (using the B1 band) and receive a tenth wireless signal having a frequency of 1960 MHz from the terrestrial cellular network (using the B1 band). A second frequency group is formed by the second frequency, the third frequency, the fourth frequency, the fifth frequency, the ninth frequency and the tenth frequency. The third antenna 36 may be formed in part by the bezel 50 and is configured to transmit a sixth wireless signal having a frequency of approximately 2.4 GHz to a terrestrial personal network and receive a seventh wireless signal having a frequency of approximately 2.4 GHz from the terrestrial personal network. A third frequency group is formed by the sixth frequency and the seventh frequency.

Accordingly, in embodiments, the wrist-worn electronic device 10 may include a first antenna 32 configured to receive location wireless signals in the GPS L1 band and/or in the GPS L5 band as well as transmit and receive NTN L band wireless signals, a second antenna 34 configured to transmit and receive communication wireless signals in the NTN and/or cellular (e.g., LTE) network frequency bands having frequencies range from approximately 700 MHz to approximately 2200 MHz, and a third antenna 36 configured to receive communication wireless signals in the 2.4 GHz frequency band or the 5 GHz frequency band.

It is to be understood that two or more antennas may be positioned in the upper portion of the housing and two or more antennas may be positioned in the lower portion of housing 12. For example, in embodiments, the wrist-worn electronic device 10 may further include a fourth antenna in the lower portion of the side wall configured to transmit and receive communication wireless signals in the 2.4 GHz frequency band or the 5 GHz frequency band. In embodiments, the wrist-worn electronic device 10 may include a first antenna 32 in the upper portion of the side wall configured to receive location wireless signals in the GPS L1 band, a second antenna 34 in the lower portion of the side wall configured to transmit and receive communication wireless signals in the 2.4 GHz frequency band, a third antenna 36 in the upper portion of the side wall configured to receive location wireless signals in the GPS L5 band, a fourth antenna in the lower portion of the side wall configured to transmit and receive communication wireless signals in the 5 GHz frequency band.

The diplexer 38 generally receives, on a first port, a first electronic signal that is a composite, or a multiplex, of a second electronic signal and a third electronic signal each having a unique frequency. The diplexer 38 demultiplexes the two signals, and outputs the second electronic signal on a second port and the third electronic signal on a third port. In addition, the diplexer 38 may receive the second electronic signal on the second port, receive the third electronic signal on the third port, multiplex the two signals, and output the multiplexed first electronic signal on the first port. The exemplary diplexer 38, as shown in FIG. 5, includes a first port (P1), a second port (P2), and a third port (P3). The diplexer 38 further includes passive or active filtering circuits, such as high-pass, low-pass, bandpass, and/or band cut filters, to separate or isolate the electronic signals. In embodiments, the first port is electrically connected to the first antenna 32 and the second and third ports are electrically connected to the location determining element 22. The first port receives the (multiplexed) composite first and second location signals, i.e., the GPS L1 band location signal and the GPS L5 band location signal, from the first antenna 32. Through filtering, the diplexer 38 demultiplexes the two location signals into separate signals. The diplexer 38 outputs the first location signal in the GPS L1 band on the second port and the second location signal in the GPS L5 band on the third port. Thus, the first antenna 32 is in electronic communication with the location determining element 22 through the diplexer 38.

Each dynamic tuning circuit 40A, 40B, 40C may be electrically coupled with one of the antennas 32, 34, 36 and generally tunes the coupled antenna 32, 34, 36 by adjusting an effective path length of the antenna 32, 34, 36, thereby adjusting a wavelength of the wireless signals received and transmitted by the antenna 32, 34, 36, and in turn, selecting which frequency bands of electronic signals that are received and transmitted. For example, in embodiments, the dynamic tuning circuit 40B may be electrically coupled with the second antenna 34, which may be configured to communicate with an NTN or terrestrial cellular (e.g., LTE) network, and cause an adjustment of an effective path length of the second antenna 34 once electrically coupled with the second antenna 34, thereby adjusting a wavelength of the wireless signals received and transmitted by the antenna, and in turn, selecting frequency bands used by the NTN or terrestrial cellular (e.g., LTE) network with which electronic signals that are wirelessly received and transmitted. Each dynamic tuning circuit 40A, 40B, 40 includes a plurality of tuning networks 56 and a multi-position electrical switch 58.

In the exemplary embodiment shown in FIG. 11, each dynamic tuning circuit 40A, 40B, 40C includes four tuning networks 56A, 56B, 56C, 56D, and the electrical switch 58 includes four positions, each selectable position electrically coupling a antenna 32, 34, 36 with a respective one of the four tuning networks 56A, 56B, 56C, 56D. Each tuning network 56 includes passive components, such as resistors, capacitors, inductors, or combinations thereof, electrically connected to one another to perform a tuning or filtering function to tune the antenna 32, 34, 36 to a particular frequency corresponding one of the frequency bands of the LTE standard and/or NTN standard. Each tuning network 56 further includes a first terminal electrically connected to the antenna 32, 34, 36 and a second terminal electrically connected to the electrical switch 58. A first tuning network 56A is configured (according to the connection architecture and values of the components) to tune the coupled antenna 32, 34, 36 to a first frequency, a second tuning network 56B is configured to tune the coupled antenna 32, 34, 36 to a second frequency, a third tuning network 56C is configured to tune the coupled antenna 32, 34, 36 to a third frequency, and a fourth tuning network 56D is configured to tune the coupled antenna 32, 34, 36 to a fourth frequency. In embodiments, the first terminals of the tuning networks 56A, 56B, 56C, 56D are electrically connected to one another and form a tuning port of the dynamic tuning circuit 40A, 40B, 40C.

For example, the first tuning network 56A may be electrically coupled (by the electrical switch 58) with the second antenna 34 and the electrical coupling causes the second antenna 34 to transmit a wireless signal at a first frequency and receive a wireless signal at a second frequency. The first frequency and the second frequency may be in a frequency group. In such an embodiment, the second antenna 34 has an effective length formed by the first portion of the circumference of the bottom plate 44, the first bottom plate conductive element 30A, the second bottom plate conductive element 30B, the first portion of the printed circuit board 26, and the first tuning network 56A. The effective length of the second antenna 34 may cause the second antenna 34 to transmit wireless signals and receive wireless signals at frequencies in the frequency group. For instance, the frequency group may include frequencies of an NTN L band, such as a first frequency corresponding to an uplink frequency of the NTN L band and the second frequency corresponds to a downlink frequency of the NTN L band. The first frequency may be approximately 1575.42 MHz and the second frequency may be approximately 1542 MHz. Similarly, the frequency group may include frequencies of a terrestrial cellular network. In such an embodiment, if the terrestrial cellular network is a long term evolution (LTE) network, the first frequency may correspond to an uplink frequency of 847 MHz (a center transmit frequency of the LTE B20 band) and the second frequency may correspond to a downlink frequency 806 MHz (a center receive frequency of the LTE B20 band).

As another example, the electrical switch 58 may electrically couple the first tuning network 56A with the second antenna 34 during a first time period, which causes the second antenna 34 to transmit a wireless signal at a first frequency and receive a wireless signal at a second frequency, and electrically couple the second tuning network 56B with the second antenna 34 during a second time period, which causes the second antenna 34 to transmit a wireless signal at a third frequency and receive a wireless signal at a fourth frequency. The first frequency and the second frequency may be in a first frequency group. The third frequency and the fourth frequency may be in a second frequency group. In such an embodiment, during the first time, the second antenna 34 has an effective length formed by the first portion of the circumference of the bottom plate 44, the first bottom plate conductive element 30A, the second bottom plate conductive element 30B, the first portion of the printed circuit board 26, and the first tuning network 56A and the effective length of the second antenna 34 may cause the second antenna 34 to transmit wireless signals and receive wireless signals at frequencies in the first frequency group. Similarly, during the second time period, the second antenna 34 has an effective length formed by the first portion of the circumference of the bottom plate 44, the first bottom plate conductive element 30A, the second bottom plate conductive element 30B, the first portion of the printed circuit board 26, and the second tuning network 56B and the effective length may cause the second antenna 34 to transmit wireless signals and receive wireless signals at frequencies in the second frequency group. For instance, the first frequency group may include frequencies of an NTN L band, such as a first frequency corresponding to an uplink frequency of the NTN L band and the second frequency corresponds to a downlink frequency of the NTN L band. The first frequency may be approximately 1575.42 MHz and the second frequency may be approximately 1542 MHz. Similarly, the second frequency group may include frequencies of a terrestrial cellular network. In such an embodiment, if the terrestrial cellular network is a long term evolution (LTE) network, the third frequency may correspond to an uplink frequency of 847 MHz (a center transmit frequency of the LTE B20 band), and the fourth frequency may correspond to a downlink frequency 806 MHz (a center receive frequency of the LTE B20 band).

For yet another example, the first antenna 32 may be configured to receive a first location signal in the GPS L1 band having a first frequency (of 1575.42 MHz) and second location signal in the GPS L5 band having a second frequency (of 1176.45 MHz) and the electrical switch 58 may electrically couple the first tuning network 56A with the second antenna 34 causing the second antenna 34 to transmit a wireless signal at a third frequency and receive a wireless signal at a fourth frequency. The first frequency and the second frequency may be in a first frequency group. The third frequency and the fourth frequency may be in a second frequency group. The first frequency group may include frequencies of the GPS L1 band and GPS L5 band. As stated above, the second frequency group may include frequencies of an NTN L band, such as a third frequency corresponding to an uplink frequency of the NTN L band and the fourth frequency corresponds to a downlink frequency of the NTN L band, or frequencies of a terrestrial cellular network, such as a long term evolution (LTE) network, where the third frequency may correspond to an uplink frequency of 847 MHz (a center transmit frequency of the LTE B20 band) and the fourth frequency may correspond to a downlink frequency of 806 MHz (a center receive frequency of the LTE B20 band). It is to be understood that other combinations involving the electrical switch 58 electrically coupling the second antenna 34 with one of the plurality of tuning networks 56 are possible and contemplated herein.

The electrical switch 58 includes a common terminal and four contacts, wherein for each of the four positions, electrical connection is made between the common terminal and a respective one of the contacts. The common terminal is electrically coupled with the second antenna 34 and the four contacts are electrically coupled with one of the first tuning network 56A, the second tuning network 56B, the third tuning network 56C or the fourth tuning network 56D. The electrical switch 58 is electrically coupled with the processor 20, which may be configured to control a position of the electrical switch 58. For example, the processor 20 may be configured to control the electrical switch 58 to select a frequency (or frequency band) from one or more bands, such as an NTN band (e.g., NTN L band, NTN S band, etc.) or a terrestrial cellular (e.g., LTE) network band. It is to be understood that references to the processor 20 may include or extend to the communication element 24, which may be similar in some functional respects to the processor 20 and configured to implement functions described herein for processor 20. Therefore, references to and the description of the communication element 24 as separate from or different to the processor 20 are not intended to limit the broad scope of functions performed by and forms of the processor 20.

In embodiments, the position of the electrical switch 58 is selected and controlled by processor 20, which may select or change the electrical switch 58 position based on or according to a value on a control line. For example, the electrical switch 58 is in a first position, with electrical connection being made between the common terminal, which is electrically coupled with the second antenna 34, and a first contact, which is electrically coupled with the first tuning network 56A, when the control line has a first value. The electrical switch 58 is in a second position, with electrical connection being made between the common terminal, which is electrically coupled with the second antenna 34, and a second contact, which is electrically coupled with the second tuning network 56B, when the control line has a second value, and so forth. Accordingly, the first tuning network 56A is selected and electrically coupled to the second antenna 34 when the electrical switch 58 is in the first position, the second tuning network 56B is selected and electrically coupled to the second antenna 34 when the electrical switch 58 is in the second position, the third tuning network 56C is selected and electrically coupled to the second antenna 34 when the electrical switch 58 is in the third position, and the fourth tuning network 56D is selected and electrically coupled to the second antenna 34 when the electrical switch 58 is in the fourth position.

As shown in FIG. 5, the dynamic tuning circuit 40B is electrically connected to the second antenna 34 with the tuning port being connected along the signal path between the second antenna 34 and the communication element 24. Depending on the position of the electrical switch 58, one of the plurality of tuning networks 56 is selected and electrically connected to the second antenna 34, which causes or tunes the second antenna 34 to operate (receive and transmit wireless signals) in a respective one of the frequency bands of the NTN and/or terrestrial cellular (e.g., LTE) network. For example, in embodiments, when the electrical switch 58 has a first selectable position electrically coupling the second antenna 34 with the first tuning network 56A, the second antenna 34 operates in the NTN L1 frequency band. When the electrical switch 58 has a second selectable position electrically coupling the second antenna 34 with the second tuning network 56B, the second antenna 34 operates in the LTE B1 and B8 frequency bands (which are utilized in Asia) and the NTN S frequency band. When the electrical switch 58 has a third selectable position electrically coupling the second antenna 34 with the third tuning network 56C, the second antenna 34 operates in the LTE B3 and B20 frequency bands (which are utilized in Europe, the Middle East, and Africa). When the electrical switch 58 has a third selectable position electrically coupling the second antenna 34 with the fourth tuning network 56D, the second antenna 34 operates in the LTE B2, B4, B12, and B28 frequency bands (which are utilized in North America, Australia, and New Zealand). In embodiments, the processor 20 is configured to control the electrical switch 80 to set its selectable position to one of the plurality of selectable positions based on a geolocation determined by the location determining element 22, which is electrically coupled with the first antenna 32 and is configured to receive one or more location signals (on frequencies associated with the GPS L1 band and/or the GPS L5 band) and determine a geolocation of the electronic device 10 based on the location signal.

Accordingly, in embodiments, the electronic device 10 may include at least the first antenna 32 formed in part by a first portion of a circumference of the bezel 50 and configured to receive location signals, the third antenna 36 formed in part by at least a first portion of a circumference of the bottom plate 44 and configured to transmit and receive communication signals from a NTN and/or a terrestrial communication network (TCN), a printed circuit board 26 positioned within the housing 12 between the bezel 50 and the bottom plate 44, the printed circuit board 26 at least partially forming a ground plane for the first antenna 32 and the second antenna 36. The electronic device 10 may also include a dynamic tuning circuit 40 having at least a first plurality of tuning networks, such as dynamic tuning circuit 40A having tuning networks 56A, 56B, 56C, 56D, that are configured to tune an electrically coupled antenna 32, 34, 36 once electrically coupled and at least a first electrical switch 58 electrically coupled with coupled antenna 32, 34, 36 and having a plurality of selectable positions, each selectable position electrically coupling the coupled antenna 32, 34, 36 with a respective one of the first plurality of tuning networks. As detailed above, in embodiments, a first of the plurality of selectable positions of the first electrical switch 58 is associated with a first tuning network 56 that causes the second antenna 36 to transmit a wireless signal at a desired frequency and receive a wireless signal at a desired frequency, the desired frequencies being in a frequency group.

The electronic device 10 may have at least one operating mode as follows. The processor 20 receives the current geolocation of the electronic device 10 from the location determining element 22. In some embodiments, the geolocation may be expressed in terms of latitude and longitude coordinates (latitude, longitude). The memory element 18 may store or retain one or more databases or tables that include global geolocation data identifying continents or global regions, wherein the global geolocation data may correspond to latitude, longitude information and one of the plurality of tuning networks 56 (as well as the selectable position of electrical switch 58) corresponding to each content or global region. The processor 20 retrieves at least a portion of the global geolocation data from the memory element 18, and compares the current geolocation to the global geolocation data to determine the continent or global region in which the electronic device 10 is currently located. The processor 20 determines one of the plurality of tuning networks 56 corresponding to the determined geolocation. In some embodiments, the processor 20 outputs a control line signal that is received by electronic switch 58 of the dynamic tuning circuit 40A causing selection of the determined one of the plurality of tuning networks 56A, 56B, 56C, 56D, corresponding the determined geolocation. In other embodiments, the control line signal is received by the communication element 24, which in turn controls the value of the control line of the electrical switch 58 in the dynamic tuning circuit 40B, 40C. Accordingly, the control line signal output by the processor 20 has a value that identifies a selectable position of electrical switch 58 to be selected based on the determined geolocation of the electronic device 10. For example, the control line signal output by the processor 20 may have a first value when the current geolocation is determined to be in Asia. The control line signal may have a second value when the current geolocation is determined to be in Europe, the Middle East, or Africa. The control line signal may have a third value when the current geolocation is determined to be in North America, Australia, or New Zealand. Thus, in embodiments, the processor 20 automatically selects the appropriate tuning network 56 for the second antenna 34 to be able to receive and transmit LTE wireless signals having frequencies in a frequency group that enables communication with an NTN and terrestrial networks and systems, such as a local cellular network, in nearly any continent or region. As detailed herein, the processor 20 may automatically determine and select a tuning network 56 based on a current geolocation of the electronic device 10 or the strength of signals received from such networks.

The processor 20 may receive strength data from the communication element 24 that may include a numerical value for the strength of communication signals from terrestrial networks and systems, such as cellular network, and NTN satellite wireless signals, such as the L1 band signal and the S band signal. Although the signal strength of communications signals from cellular network are typically adequate for voice and data communications while the electronic device 10 is located in a coverage area of the cellular network, the signal strength of those communications signals may be weak or insufficient in certain geolocations where the electronic device 10 is able to receive NTN satellite wireless signals. Based on the signal strength of communications signals, the processor 20 may identify the appropriate network, determine the frequencies of electronic signals to be transmitted and received by the electronic device 10 in order to communicate with that network and automatically select the tuning network 56 of the dynamic tuning circuit 40A, 40B, 40C by controlling the electronic switch 58 that will cause an adjustment of an effective path length of a antenna 32, 34, 36, thereby adjusting a wavelength of the wireless signals received and transmitted by the antenna 32, 34, 36, and in turn, selecting frequency bands to be used for communication with the NTN or terrestrial cellular (e.g., LTE) network. In embodiments, if the electronic device 10 is using NTN communication and the processor 20 determines that the signal strength of the NTN L1 band is greater than the signal strength of the NTN S band, then the processor 20 outputs the control line signal that will cause the electronic switch 58 to change from a current tuning network 56 (e.g., the first tuning network 56A) to another tuning network 56 (e.g., the fourth tuning network 56D). Similarly, if the electronic device 10 is using NTN communication and the processor 20 determines that the signal strength of the NTN S band is greater than the signal strength of the NTN L1 band, then the processor 20 outputs the control line signal that will cause the electronic switch 58 to change from a current tuning network 56 (e.g., the fourth tuning network 56D) to another tuning network 56 (e.g., the first tuning network 56A).

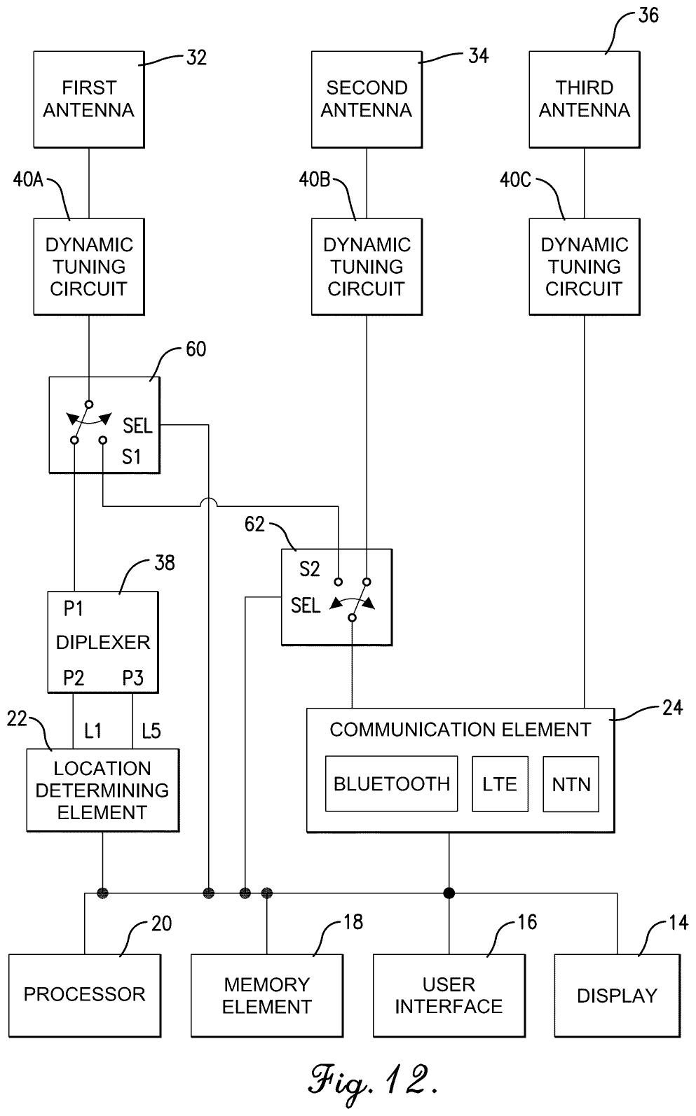

Referring to FIG. 12, another embodiment of the electronic device 100 is shown. The electronic device 100 includes the same components as the electronic device 10, shown in FIG. 5 and discussed above. The electronic device 100 additionally includes a first toggle switch 60 (labelled “S1” in FIG. 12) and a second toggle switch 62 (labelled “S2” in FIG. 12), each of which, select the usage or function of the first antenna 32 and the second antenna 34, respectively.

Each toggle switch 60, 62 includes a common terminal, a first contact, and a second contact and operates in two selectable positions. In a first selectable position, an electrical connection is made between the common terminal and the first contact of each toggle switch 60, 62. In a second selectable position, an electrical connection is made between the common terminal and the second contact of each toggle switch 60, 62. The position of the toggle switch 60, 62 is selected according to a value of a control line, wherein the first position is selected when the control line has a first value, and the second position is selected when the control line has a second value.

For the first toggle switch 60, the common terminal is electrically connected to the first antenna 32, the first contact is electrically connected to the first port of the diplexer 38, and the second contact is electrically connected to the second contact of the second toggle switch 62. For the second toggle switch 62, the common terminal is electrically connected to the communication element 24 and the first contact is electrically connected to the second antenna 34. The control lines of the first and second toggle switches 60, 62 are in electronic communication with the processor 20, which outputs a control signal to select the selectable position of the first and second toggle switches 60, 62.

The electronic device 100 may operate, at least in part, as follows. The processor 20 outputs a first control line signal received by the first toggle switch 60 and a second control line signal received by the second toggle switch 62. In a default mode or user-selected mode, the processor 20 outputs the first control line signal and the second control line signal having the first value, which causes the first toggle switch 60 and the second toggle switch 62 to each be set in the first position, as depicted in FIG. 12. Thus, the first antenna 32 is electrically connected to the diplexer 38 (and the location determining element 22), and the second antenna 34 is electrically connected to the communication element 24. In this configuration, the electronic device 100 may operate or function as described above for the electronic device 10.

In some embodiments, when the user desires to use the first antenna 32 (instead of the second antenna 32) to communicate with the NTN, by transmitting wireless signals and receiving wireless signals on NTN L1 band, a different mode of operation for the electronic device 100 may be selected through the user interface 16. In response to the processor 20 receiving the mode change from the user interface 16, processor 20 outputs the first control line signal and the second control line signal having the second value. In response, the first toggle switch 60 and the second toggle switch 62 are each set in the second position causing the first antenna 32 to be electrically connected through the second toggle switch 62 to the communication element 24. In this configuration, the second antenna 34 is disconnected (at least temporarily). This allows for the communication element 24 to communicate (transmit and receive) signals through the first antenna 32 which is configured (by default and without the need for retuning) to communicate signals in the L band. In some embodiments or operating modes, the first and second toggle switches 60, 62 may remain in this configuration until the user selects a different (perhaps the previous) operating mode.

In other embodiments or operating modes, the processor 20 may change the values of the first and second control line signals, which, in turn, changes the positions of the first and second toggle switches 60, 62 and the connectivity of the first antenna 32 and the second antenna 34, in accordance with a time schedule, a geolocation of the electronic device 10, a signal strength of the LTE wireless signals and the NTN wireless signals, or other criteria.

For example, in a first operating mode, the processor 20 may output the first and second control line signals having the first value, which sets the first and second toggle switches 60, 62 to the first position, thereby electrically connecting the first antenna 32 to the location determining element 22 and the second antenna 34 to the communication element 24, for a first period of time. At the end of the first period of time, the processor 20 may output the first and second control line signals having the second value, which sets the first and second toggle switches 60, 62 to the second position, thereby electrically connecting the first antenna 32 to the communication element 24 and disconnecting the second antenna 34, for a second period of time. At the end of the second period of time, the processor 20 may output the first and second control line signals having the first value for the first period of time followed by outputting the first and second control line signals having the second value for the second period of time in a repetitive cycle. In this first operating mode, the communication element 24 may switch back and forth between transmitting and receiving signals in the terrestrial cellular LTE bands along with the NTN S bands (while the first and second toggle switches 60, 62 are in the first position) and transmitting and receiving signals in the NTN L bands (while the first and second toggle switches 60, 62 are in the second position). This may allow the communication element 24 to communicate signals in the NTN S bands and the NTN L bands without having to re-tune the second antenna 34.

In a second operating mode, the processor 20 may output the first and second control line signals having the first value when GNSS location services are desired as the location determining element 22 will receive location signals from the first antenna 32 in this configuration. When GNSS location services are not desired, the processor 20 may output the first and second control line signals having the second value, which would cause the location determining element 22 to no longer receive location signals from the first antenna 32 as the first antenna 22 is being used to communicate with NTN in this configuration.

In a third operating mode, once the processor 20 determines that the signal strength of the NTN S band signals is greater than the signal strength of the NTN L band signals or when GNSS location services are desired by the user, the processor 20 may output the first and second control line signals having the first value. In this configuration, the first antenna 32 is electrically connected to the diplexer 38 and the location determining element 22, and the second antenna 34 is electrically connected to the communication element 24. Once the processor 20 determines the signal strength of the NTN L band signals is greater than the signal strength of the NTN S band signals or when GNSS location services are not desired by the user, the processor 20 may output the first and second control line signals having the second value. In this configuration, the first antenna 32 is electrically connected through the second toggle switch 62 to the communication element 24 and the second antenna 34 is disconnected.

Using these operating modes, based on functionality desired by the user or determined signal strength of NTN wireless signals or other criteria, the processor 20 may be configured to control the position of the toggle switches 60, 62 to electrically couple the first antenna 32 with the location determining element 22 and the communication element 24 in accordance with a time schedule (sharing), a geolocation of the electronic device 10, a determined signal strength of the LTE wireless signals and the NTN wireless signals, or other criteria.

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processor, may be implemented as special purpose or as general purpose. For example, the processor may comprise dedicated circuitry or logic that is permanently configured, such as an application-specific integrated circuit (ASIC), or indefinitely configured, such as an FPGA, to perform certain operations. The processor may also comprise programmable logic or circuitry (e.g., as encompassed within a general-purpose processor or other programmable processor) that is temporarily configured by software to perform certain operations. It will be appreciated that the decision to implement the processor as special purpose, in dedicated and permanently configured circuitry, or as general purpose (e.g., configured by software) may be driven by cost and time considerations.

Accordingly, the term “processor” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processor is temporarily configured (e.g., programmed), each of the processors need not be configured or instantiated at any one instance in time. For example, where the processor comprises a general-purpose processor configured using software, the general-purpose processor may be configured as respective different processors at different times. Software may accordingly configure the processor to constitute a particular hardware configuration at one instance of time and to constitute a different hardware configuration at a different instance of time.

Computer hardware components, such as communication elements, memory elements, processors, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some example embodiments, the processors may be located in a single location (e.g., within a home environment, an office environment or as a server farm), while in other embodiments the processors may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. A wrist-worn electronic device comprising:
a bezel retainer formed from electrically non-conductive material;
a lower ring formed from electrically non-conductive material;
a housing including a circumferential side wall, a bezel coupled to an upper surface of the bezel retainer, and a bottom plate coupled to a lower surface of the lower ring;
a first antenna formed in part by a first portion of a circumference of the bezel, the first antenna configured to receive a first wireless signal, the first wireless signal being a first location signal having a first frequency in a first frequency group including a first of a plurality of global navigation satellite system (GNSS) bands;
a second antenna formed in part by at least a first portion of a circumference of the bottom plate, the second antenna configured to transmit a second wireless signal to a non-terrestrial network (NTN), receive a third wireless signal from the NTN, or both;
a first plurality of tuning networks, each tuning network of the first plurality of tuning networks configured to tune the second antenna once electrically coupled with the second antenna; and
a first electrical switch electrically coupled with the second antenna and having a plurality of selectable positions, each selectable position electrically coupling the second antenna with a respective one of the first plurality of tuning networks;
wherein the bezel, the side wall and the bottom plate are each formed from electrically conductive material; and
wherein a first of the plurality of selectable positions of the first electrical switch is associated with a first tuning network that causes the second antenna to transmit the second wireless signal at a second frequency and receive the third wireless signal at a third frequency, the second frequency and the third frequency being in a second frequency group.

2. The wrist-worn electronic device of claim 1, further comprising a location determining element and a processor, the processor electrically coupled with the electrical switch and the location determining element;
wherein the location determining element is electrically coupled with the first antenna and is configured to receive the first location signal and determine a geolocation of the electronic device based on the first location signal; and
wherein the processor is configured to control the first electrical switch to set its selectable position to one of the plurality of selectable positions based on the determined geolocation.

3. The wrist-worn electronic device of claim 2, wherein the first frequency group includes frequencies corresponding to at least one of the global positioning system (GPS) L1 band and the GPS L5 band, wherein the second frequency corresponds to an uplink frequency of the NTN L band and the third frequency corresponds to a downlink frequency of the NTN L band.

4. The wrist-worn electronic device of claim 3, wherein the first frequency is approximately 1575.42 megahertz (MHz), wherein the second frequency corresponds to the uplink frequency of the NTN L band of approximately 1643 MHz, and wherein the third frequency corresponds to the downlink frequency of the NTN L band of approximately 1542 MHz.

5. The wrist-worn electronic device of claim 3, wherein the second frequency group further includes one or more frequencies of a terrestrial cellular network, wherein the second antenna is configured to transmit a fourth wireless signal to the terrestrial cellular network at a fourth frequency and receive a fifth wireless signal from the terrestrial cellular network at a fifth frequency.

6. The wrist-worn electronic device of claim 5, wherein the terrestrial cellular network is a long-term evolution (LTE) network, wherein the first frequency is approximately 1575.42 megahertz (MHz), wherein the fourth frequency corresponds to an uplink frequency of 847 MHz, and wherein the fifth frequency corresponding to a downlink frequency of 806 MHz.

7. The wrist-worn electronic device of claim 1, wherein a second of the plurality of selectable positions of the first electrical switch is associated with a second tuning network that causes the second antenna to transmit a fourth wireless signal at a fourth frequency, receive a fifth wireless signal at a fifth frequency, the fourth frequency and the fifth frequency being in the second frequency group and each corresponding to one or more frequencies of a terrestrial cellular network.

8. The wrist-worn electronic device of claim 1, further comprising a signal feed bottom plate conductive element and a second bottom plate conductive element each positioned between the bottom plate and the lower ring, wherein the second antenna is a loop antenna and the first portion of the circumference of the bottom plate extends between the signal feed bottom plate conductive element and the second bottom plate conductive element.

9. The wrist-worn electronic device of claim 1, further comprising a first signal feed bezel conductive element, a first bezel conductive element and a second bezel conductive element positioned between the bezel and the bezel retainer,
wherein the first portion of the circumference of the bezel extends between the first bezel conductive element and the second bezel conductive element, wherein the first signal feed bezel conductive element is positioned between the first bottom plate conductive element and the second bottom plate conductive element.

10. The wrist-worn electronic device of claim 9, further comprising a first signal feed bottom plate conductive element, a first bottom plate conductive element and a second bottom plate conductive element each positioned between the bottom plate and the lower ring, the first signal feed bottom plate conductive element positioned between the first bottom plate conductive element and the second bottom plate conductive element;
wherein the second antenna is a slot antenna formed in part by the first portion of the circumference of the bottom plate extending between the first bottom plate conductive element and the second bottom plate conductive element and a first portion of the lower ring extending between the first bottom plate conductive element and the second bottom plate conductive element, the second antenna having an effective length that is the sum of a length of the first portion of the circumference of the bottom plate, a length of the first bottom plate conductive element, a length of the second bottom plate conductive element, a length of the first portion of the lower ring, and the respective one of the plurality of tuning networks.

11. The wrist-worn electronic device of claim 2, further comprising a printed circuit board, a plurality of electrical contacts, a second plurality of tuning networks and a second electrical switch, the second plurality of tuning networks associated with the second electrical switch and each tuning network of the second plurality of tuning networks configured to tune the first antenna once electrically coupled with the first antenna, the second electrical switch electrically coupled with the first antenna and the processor, the second electrical switch having a plurality of selectable positions, each selectable position electrically coupling the first antenna with a respective one of the second plurality of tuning networks;
wherein the first electrical switch and the first plurality of tuning networks are positioned on the printed circuit board, the first electrical switch and each of the plurality of tuning networks of the first plurality of tuning networks associated with the first electrical switch forming a first dynamic tuning circuit;
wherein the second electrical switch and the second plurality of tuning networks are positioned on the printed circuit board, the second electrical switch and each of the plurality of tuning networks of the second plurality of tuning networks associated with the second electrical switch forming a second dynamic tuning circuit; and
wherein at least one of the plurality of electrical contacts electrically couple the side wall with an electrical ground of the printed circuit board.

12. A wrist-worn electronic device comprising:
a bezel retainer formed from electrically non-conductive material;
a lower ring formed from electrically non-conductive material;
a housing including a circumferential side wall, a bezel coupled to an upper surface of the bezel retainer, and a bottom plate coupled to a lower surface of the lower ring;
a first antenna formed in part by a first portion of a circumference of the bezel, the first antenna configured to receive a first wireless signal, the first wireless signal being a location signal having a first frequency in a first frequency group including a first of a plurality of global navigation satellite system (GNSS) bands;
a second antenna formed in part by at least a first portion of a circumference of the bottom plate, the second antenna configured to transmit a second wireless signal to a non-terrestrial network (NTN), receive a third wireless signal from the NTN, or both;
a first plurality of tuning networks, each tuning network of the first plurality of tuning networks configured to tune the second antenna once electrically coupled with the second antenna;
a first electrical switch electrically coupled with the second antenna and having a plurality of selectable positions, each selectable position electrically coupling the second antenna with a respective one of the first plurality of tuning networks; and
a processor electrically coupled with the first electrical switch, the processor configured to control the first electrical switch to set its selectable position to a first of the plurality of selectable positions associated with a first tuning network that causes the second antenna to transmit the second wireless signal at a second frequency and receive the third wireless signal at a third frequency, the second frequency and the third frequency being in a second frequency group;
wherein the bezel, the side wall and the bottom plate are each formed from electrically conductive material.

13. The wrist-worn electronic device of claim 12, further comprising a location determining element electrically coupled with the first antenna, the location determining element configured to receive the first location signal and determine a geolocation of the electronic device based on the first location signal;
wherein the first frequency group includes frequencies corresponding to at least one of the global positioning system (GPS) L1 band and the GPS L5 band; and
wherein the processor is further configured to control the first electrical switch to select one of the plurality of selectable positions based on the determined geolocation.

14. The wrist-worn electronic device of claim 13, wherein the first frequency corresponds to a global positioning system (GPS) L1 band having a center frequency of approximately 1575.42 megahertz (MHz), the second frequency corresponds to an uplink frequency of the NTN L band of approximately 1643 MHz and the third frequency corresponds to a downlink on an L band of the NTN of approximately 1542 MHz.

15. The wrist-worn electronic device of claim 12, wherein the second frequency group further includes one or more frequencies of a terrestrial cellular network, wherein the second antenna is configured to transmit a fourth wireless signal to the terrestrial cellular network at a fourth frequency and receive a fifth wireless signal from the terrestrial cellular network at a fifth frequency.

16. The wrist-worn electronic device of claim 12, wherein a second of the plurality of selectable positions of the first electrical switch is associated with a second tuning network that causes the second antenna to transmit a fourth wireless signal at a fourth frequency, receive a fifth wireless signal at a fifth frequency, the fourth frequency and the fifth frequency being in the second frequency group and each corresponding to one or more frequencies of a terrestrial cellular network.

17. The wrist-worn electronic device of claim 12, further comprising a printed circuit board, a plurality of electrical contacts, a second plurality of tuning networks and a second electrical switch, the second plurality of tuning networks associated with the second electrical switch and each tuning network of the second plurality of tuning networks configured to tune the first antenna once electrically coupled with the first antenna, the second electrical switch electrically coupled with the first antenna and the processor, the second electrical switch having a plurality of selectable positions, each selectable position electrically coupling the first antenna with a respective one of the second plurality of tuning networks;
wherein the first electrical switch and the first plurality of tuning networks are positioned on the printed circuit board, the first electrical switch and each of the first plurality of tuning networks associated with the first electrical switch forming a first dynamic tuning circuit;
wherein the second electrical switch and the second plurality of tuning networks are positioned on the printed circuit board, the second electrical switch and each of the second plurality of tuning networks associated with the second electrical switch forming a second dynamic tuning circuit; and
wherein at least one of the plurality of electrical contacts electrically couple the side wall with an electrical ground of the printed circuit board.

18. A wrist-worn electronic device comprising:
a bezel retainer formed from electrically non-conductive material;
a lower ring formed from electrically non-conductive material;
a housing including a circumferential side wall, a bezel coupled to an upper surface of the bezel retainer, and a bottom plate coupled to a lower surface of the lower ring;
a first antenna formed in part by a first portion of a circumference of the bezel, the first antenna configured to receive a first wireless signal, the first wireless signal being a first location signal having a first frequency in a first frequency group including a first of a plurality of global navigation satellite system (GNSS) bands;
a second antenna formed in part by at least a first portion of a circumference of the bottom plate, the second antenna configured to transmit a second wireless signal to a non-terrestrial network (NTN), receive a third wireless signal from the NTN, or both;
a first plurality of tuning networks, each tuning network of the first plurality of tuning networks configured to tune the second antenna once electrically coupled with the second antenna;
a first electrical switch electrically coupled with the second antenna and having a plurality of selectable positions, each selectable position electrically coupling the second antenna with a respective one of the first plurality of tuning networks;
a location determining element electrically coupled with the first antenna and configured to receive the first location signal and determine a geolocation of the electronic device based on the first location signal; and
a processor electrically coupled with the first electrical switch and the location determining element, the processor configured to control the first electrical switch to set its selectable position to a first of the plurality of selectable positions associated with a first tuning network that causes the second antenna to transmit the second wireless signal at a second frequency and receive the third wireless signal at a third frequency, the second frequency and the third frequency being in a second frequency group;
wherein the bezel, the side wall and the bottom plate are each formed from electrically conductive material; and
wherein the processor controls the first electrical switch to set its selectable position to one of the plurality of selectable positions and select one of the first plurality of tuning networks based on the determined geolocation.

19. The wrist-worn electronic device of claim 18, wherein the first frequency group includes frequencies corresponding to at least one of the global positioning system (GPS) L1 band and the GPS L5 band;
wherein the second frequency group further includes one or more frequencies of a terrestrial cellular network; and
wherein a second of the plurality of selectable positions of the first electrical switch is associated with a second tuning network that causes the second antenna to transmit the fourth wireless signal to the terrestrial cellular network at a fourth frequency, receive a fifth wireless signal from the terrestrial cellular network at a fifth frequency.

20. The wrist-worn electronic device of claim 18, further comprising a printed circuit board, a plurality of electrical contacts, a second plurality of tuning networks and a second electrical switch, the second plurality of tuning networks associated with the second electrical switch and each tuning network of the second plurality of tuning networks configured to tune the first antenna once electrically coupled with the first antenna, the second electrical switch electrically coupled with the first antenna and the processor, the second electrical switch having a plurality of selectable positions, each selectable position electrically coupling the first antenna with a respective one of the second plurality of tuning networks;
wherein the first electrical switch and the first plurality of tuning networks associated with the first electrical switch are positioned on the printed circuit board, the first electrical switch and each of the first plurality of tuning networks associated with the first electrical switch forming a first dynamic tuning circuit;
wherein the second electrical switch and the second plurality of tuning networks are positioned on the printed circuit board, the second electrical switch and each of the second plurality of tuning networks associated with the second electrical switch forming a second dynamic tuning circuit; and
wherein at least one of the plurality of electrical contacts electrically couple the side wall with an electrical ground of the printed circuit board.
